(19) United States
(12) Patent Application Publication
(10) Pub. No.: US 2024/0256275 A1
(43) Pub. Date: Aug. 1, 2024

(54) EFFICIENT FORWARD-ERROR-CORRECTION PROTOCOL BASED ON XOR OPERATIONS AND A SPARSE GRAPH

(71) Applicant: VMware LLC, Palo Alto, CA (US)

(72) Inventor: Amol Dixit, Palo Alto, CA (US)

(73) Assignee: VMware LLC, Palo Alto, CA (US)

(21) Appl. No.: 18/104,593

(22) Filed: Feb. 1, 2023

(51) Int. Cl. G06F 9/30

(52) U.S. Cl. CPC G06F 9/30029; G06F 9/30149; G06F 11/1004; H04L 1/0046; H04L 1/0061

(57) ABSTRACT

The current document is directed to an improved communications protocol that encompasses XOR-based forward error correction and that uses dynamic check-packet graphs that provide for efficient recovery of packets for which transmission has failed. During the past 20 years, XOR-based forward-error-correction (“FEC”) communications protocols have been developed to provide reliable multi-packet message transmission with relatively low latencies and computational complexity. These XOR-based FEC communications protocols, however, are associated with a significant amount of redundant-data transmission to achieve reliable multi-packet message transmission. The currently disclosed XOR-based FEC communications protocol employs dynamic, sparse check-packet graphs that provide for receiver-side packet recovery with significantly less redundant-data transmission. Because less redundant data needs to be transmitted in order to guarantee reliable multi-packet message delivery, the currently disclosed XOR-based FEC communications protocols are associated with significantly smaller temporal latencies and provide for greater data-transmission bandwidth.

### TECHNICAL FIELD

The current document is directed to communications protocols and, in particular, to a communication protocol that encompasses XOR-based forward error correction and dynamic, sparse check-packet graphs that provide for efficient packet recovery.

### BACKGROUND

Communications hardware and communications protocols provide a fundamental basis for modern computer networking and distributed computer systems. Communications protocols provide many different types of communications services above point-to-point data-frame transfer provided by communications hardware. In general, communications protocols are stacked in layers, with each layer using the communications services provided by the layers below them to provide additional communications services. In many models, the lowest layer of a communications-protocol stack is the hardware layer. The additional communications services provided by higher-level communications protocols include error detection and correction, data-frame addressing and routing, communications traffic control, establishment of communications connections between communicating entities, establishment and management of multi-packet message transmission, establishment and management of communications sessions in which multiple messages are transmitted and received, data compression and encryption, and many other services.

A number of different communications protocols have been developed to address the problem of reliable delivery of frames or packets that together comprise multi-frame or multi-packet messages. Examples include automatic repeat request (“ARQ”) and forward error correction (“FEC”) protocols. In general, reliable delivery of frames or packets is provided at the expense of temporal transmission latencies and transmission of additional, redundant data. Designers, developers, and users of network communications and the communications protocols that implement network communications continuously seek improvements in communications protocols that result in greater efficiency and data transfer while, at the same time, providing desired levels of reliability.

### SUMMARY

The current document is directed to an improved communications protocol that encompasses XOR-based forward error correction and that uses dynamic check-packet graphs that provide for efficient recovery of packets for which transmission has failed. During the past 20 years, XOR-based forward-error-correction (“FEC”) communications protocols have been developed to provide reliable multi-packet message transmission with relatively low latencies and computational complexity. These XOR-based FEC communications protocols, however, are associated with a significant amount of redundant-data transmission to achieve reliable multi-packet message transmission. The currently disclosed XOR-based FEC communications protocol employs dynamic, sparse check-packet graphs that provide for receiver-side packet recovery with significantly less redundant-data transmission. Because less redundant data needs to be transmitted in order to guarantee reliable multi-packet message delivery, the currently disclosed XOR-based FEC communications protocols are associated with significantly smaller temporal latencies and provide for greater data-transmission bandwidth.

### BRIEF DESCRIPTION OF THE DRAWINGS

FIG. 1 provides a general architectural diagram for various types of computers.

FIG. 2 illustrates an Internet-connected distributed computer system.

FIG. 3 illustrates cloud computing.

FIG. 4 illustrates generalized hardware and software components of a general-purpose computer system, such as a general-purpose computer system having an architecture similar to that shown in FIG. 1.

FIGS. 5A-D illustrate two types of virtual machine and virtual-machine execution environments.

FIG. 6 illustrates a communications protocol stack.

FIGS. 7A-G illustrate multi-packet message transmission.

FIG. 8 illustrates one communications-protocol approach to increasing the reliability of multi-packet-message transmission in view of the unreliability of packet transmission.

FIGS. 9A-D illustrate an example of an ARQ communications protocol.

FIG. 10 illustrates encoding of redundant information into a multi-packet message by a sender that allows the receiver of the multi-packet message to automatically recover packets for which transmission has failed.

FIGS. 11A-B illustrate an FEC-based communications protocol for increasing the reliability of multi-packet-message transmission.

FIGS. 12A-C illustrate XOR-based check packets.

FIG. 13 illustrates a communications-protocol environment in which the currently disclosed communications protocol is incorporated.

FIGS. 14A-B illustrate a data structure that is used on the receiver side to implement the currently disclosed FEC-based communications protocol.

FIGS. 15A-R illustrate operation of the currently disclosed communications protocol with respect to one partition of the data structure discussed with reference to FIGS. 14A-B.

FIG. 16 provides a control-flow diagram for a sender-side routine that sends a message to a receiver using the currently disclosed communications protocol.

FIG. 17 provides a control-flow diagram for the routine “send.” called in step 1614 of FIG. 16.

FIG. 18 provides a control-flow diagram for the routine “send check” called in step 1707 of FIG. 17.

FIG. 19 provides a control-flow diagram for the routine “scroll” called in step 1618 of FIG. 16.

FIG. 20 provides a control-flow diagram for the sender-receiver thread launched in step 1606 of FIG. 16.

FIG. 21 provides a control-flow diagram for a receiver that receives multi-packet messages according to the currently disclosed communications protocol.

FIG. 22 provides a control-flow diagram for the check-timer handler called in step 2108 of FIG. 21.

FIG. 23 provides a control-flow diagram for the packet-timer handler called in step 2112 of FIG. 21.

FIGS. 24A-B provide a control-flow diagram for the routine “packet.” called in step 2116 of FIG. 21.

FIG. 25 provides a control flow diagram for the routine “new message,” called in step 2410 of FIG. 24A.

FIG. 26 provides a control-flow diagram for the routine “num received,” called from various other routines, including from the routine “packet timer” in step 2304 and the routine “check timer” in step 2214.

FIG. 27 provides a control-flow diagram for the routine “message complete,” called in various other routines, including in step 2438 of FIG. 24B.

FIG. 28 provides a control-flow diagram for the routine “check.” called in step 2120 of FIG. 21.

FIG. 29 provides a control-flow diagram for the routine “add new packet,” called in several other routines, including in step 2020 of FIG. 28.

FIG. 30 provides a control-flow diagram for the routine “walk,” called in step 2911 of FIG. 29.

FIG. 31 provides a control-flow diagram for the routine “cascade,” called in step 2824 of FIG. 28.

FIG. 32 provides a control-flow diagram for the routine “h walk,” called in step 2824 of FIG. 28.

FIG. 33 provides a control-flow diagram for the routine “finish.” called in step 2810 of FIG. 28.

### DETAILED DESCRIPTION

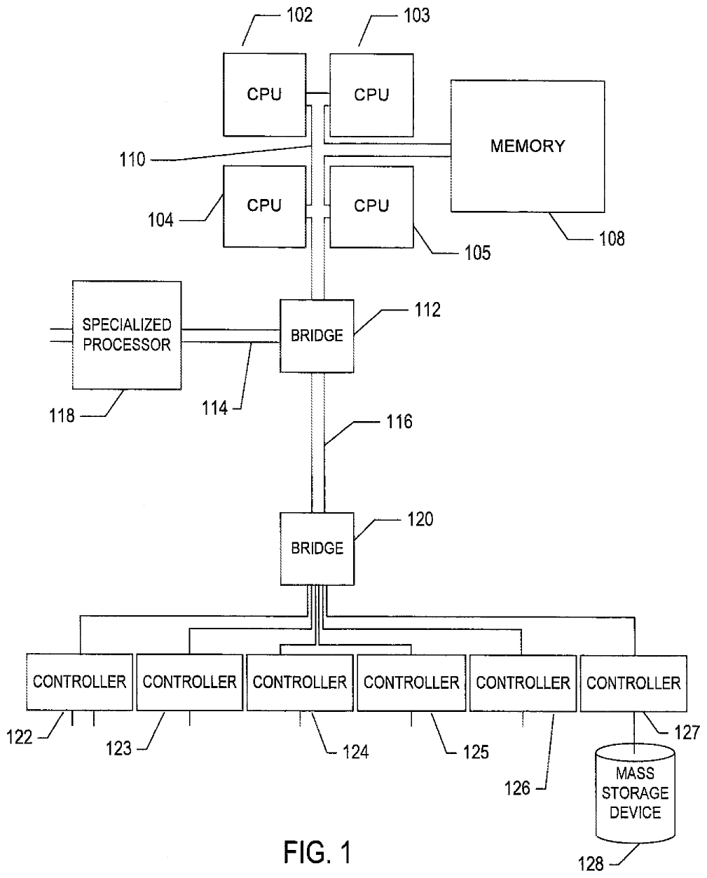

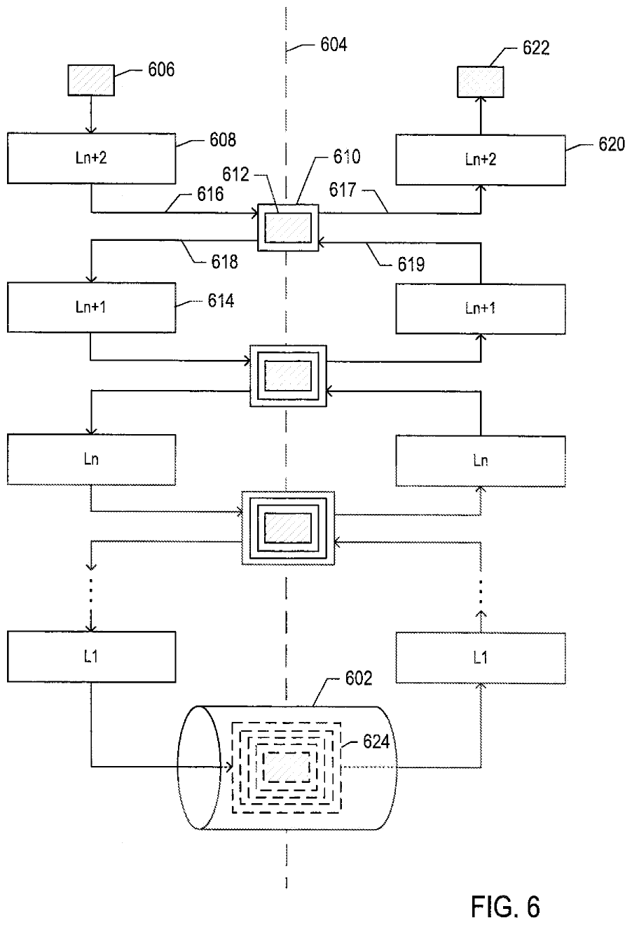

The current document is directed to communications protocols that encompass XOR-based forward error correction and that use dynamic check-packet graphs that provide for efficient packet recovery. In a first subsection, below, a description of computer hardware, complex computational systems, and virtualization is provided with reference to FIGS. 1-SD. In a second subsection, the currently disclosed methods and systems are discussed with reference to FIGS. 6-32.

### Computer Hardware, Complex Computational Systems, and Virtualization

The term “abstraction” is not, in any way, intended to mean or suggest an abstract idea or concept. Computational abstractions are tangible, physical interfaces that are implemented, ultimately, using physical computer hardware, data-storage devices, and communications systems. Instead, the term “abstraction” refers, in the current discussion, to a logical level of functionality encapsulated within one or more concrete, tangible, physically-implemented computer systems with defined interfaces through which electronically-encoded data is exchanged, process execution launched, and electronic services are provided. Interfaces may include graphical and textual data displayed on physical display devices as well as computer programs and routines that control physical computer processors to carry out various tasks and operations and that are invoked through electronically implemented application programming interfaces (“APIs”) and other electronically implemented interfaces. There is a tendency among those unfamiliar with modern technology and science to misinterpret the terms “abstract” and “abstraction,” when used to describe certain aspects of modern computing. For example, one frequently encounters assertions that, because a computational system is described in terms of abstractions, functional layers, and interfaces, the computational system is somehow different from a physical machine or device. Such allegations are unfounded. One only needs to disconnect a computer system or group of computer systems from their respective power supplies to appreciate the physical, machine nature of complex computer technologies. One also frequently encounters statements that characterize a computational technology as being “only software,” and thus not a machine or device. Software is essentially a sequence of encoded symbols, such as a printout of a computer program or digitally encoded computer instructions sequentially stored in a file on an optical disk or within an electromechanical mass-storage device. Software alone can do nothing. It is only when encoded computer instructions are loaded into an electronic memory within a computer system and executed on a physical processor that so-called “software implemented” functionality is provided. The digitally encoded computer instructions are an essential and physical control component of processor-controlled machines and devices, no less essential and physical than a cam-shaft control system in an internal-combustion engine. Multi-cloud aggregations, cloud-computing services, virtual-machine containers and virtual machines, communications interfaces, and many of the other topics discussed below are tangible, physical components of physical, electro-optical-mechanical computer systems.

FIG. 1 provides a general architectural diagram for various types of computers. The computer system contains one or multiple central processing units (“CPUs”) 102-105, one or more electronic memories 108 interconnected with the CPUs by a CPU/memory-subsystem bus 110 or multiple busses, a first bridge 112 that interconnects the CPU/memory-subsystem bus 110 with additional busses 114 and 116, or other types of high-speed interconnection media, including multiple, high-speed serial interconnects. These busses or serial interconnections, in turn, connect the CPUs and memory with specialized processors, such as a graphics processor 118, and with one or more additional bridges 120, which are interconnected with high-speed serial links or with multiple controllers 122-127, such as controller 127, that provide access to various different types of mass-storage devices 128, electronic displays, input devices, and other such components, subcomponents, and computational resources. It should be noted that computer-readable data-storage devices include optical and electromagnetic disks, electronic memories, and other physical data-storage devices. Those familiar with modern science and technology appreciate that electromagnetic radiation and propagating signals do not store data for subsequent retrieval and can transiently “store” only a byte or less of information per mile, far less information than needed to encode even the simplest of routines.

Of course, there are many different types of computer-system architectures that differ from one another in the number of different memories, including different types of hierarchical cache memories, the number of processors and the connectivity of the processors with other system components, the number of internal communications busses and serial links, and in many other ways. However, computer systems generally execute stored programs by fetching instructions from memory and executing the instructions in one or more processors. Computer systems include general-purpose computer systems, such as personal computers (“PCs”), various types of servers and workstations, and higher-end mainframe computers, but may also include a plethora of various types of special-purpose computing devices, including data-storage systems, communications routers, network nodes, tablet computers, and mobile telephones.

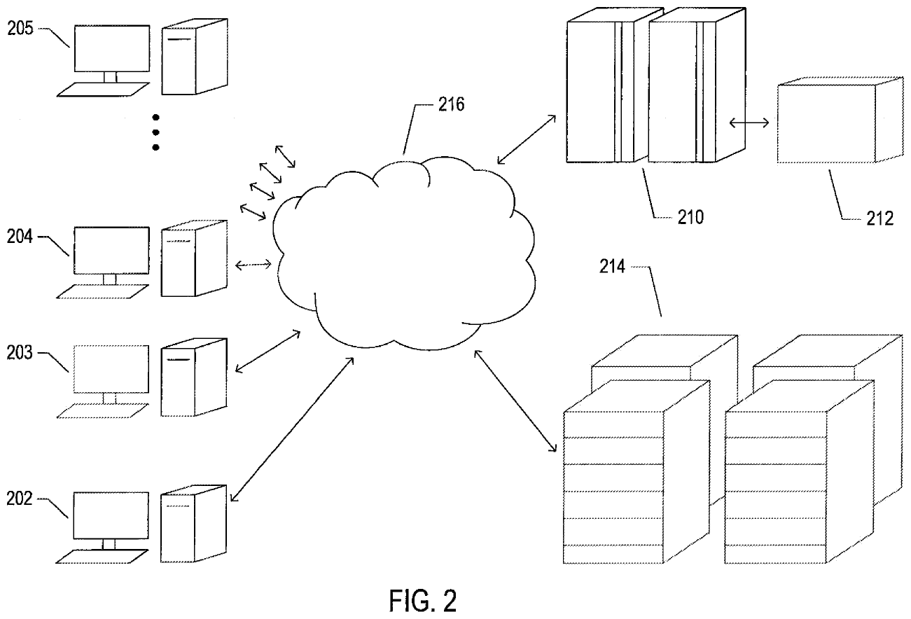

FIG. 2 illustrates an Internet-connected distributed computer system. As communications and networking technologies have evolved in capability and accessibility, and as the computational bandwidths, data-storage capacities, and other capabilities and capacities of various types of computer systems have steadily and rapidly increased, much of modern computing now generally involves large distributed systems and computers interconnected by local networks, wide-area networks, wireless communications, and the Internet. FIG. 2 shows a typical distributed system in which a large number of PCs 202-205, a high-end distributed mainframe system 210 with a large data-storage system 212, and a large computer center 214 with large numbers of rack-mounted servers or blade servers all interconnected through various communications and networking systems that together comprise the Internet 216. Such distributed computer systems provide diverse arrays of functionalities. For example, a PC user sitting in a home office may access hundreds of millions of different web sites provided by hundreds of thousands of different web servers throughout the world and may access high-computational-bandwidth computing services from remote computer facilities for running complex computational tasks.

Until recently, computational services were generally provided by computer systems and data centers purchased, configured, managed, and maintained by service-provider organizations. For example, an e-commerce retailer generally purchased, configured, managed, and maintained a data center including numerous web servers, back-end computer systems, and data-storage systems for serving web pages to remote customers, receiving orders through the web-page interface, processing the orders, tracking completed orders, and other myriad different tasks associated with an e-commerce enterprise.

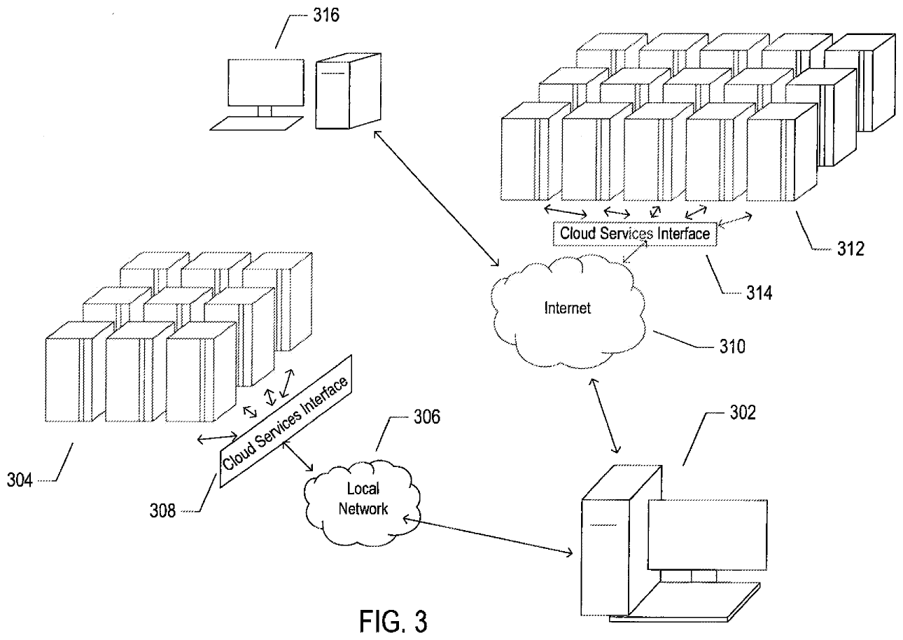

FIG. 3 illustrates cloud computing. In the recently developed cloud-computing paradigm, computing cycles and data-storage facilities are provided to organizations and individuals by cloud-computing providers. In addition, larger organizations may elect to establish private cloud-computing facilities in addition to, or instead of, subscribing to computing services provided by public cloud-computing service providers. In FIG. 3, a system administrator for an organization, using a PC 302, accesses the organization's private cloud 304 through a local network 306 and private-cloud interface 308 and also accesses, through the Internet 310, a public cloud 312 through a public-cloud services interface 314. The administrator can, in either the case of the private cloud 304 or public cloud 312, configure virtual computer systems and even entire virtual data centers and launch execution of application programs on the virtual computer systems and virtual data centers in order to carry out any of many different types of computational tasks. As one example, a small organization may configure and run a virtual data center within a public cloud that executes web servers to provide an e-commerce interface through the public cloud to remote customers of the organization, such as a user viewing the organization's e-commerce web pages on a remote user system 316.

Cloud-computing facilities are intended to provide computational bandwidth and data-storage services much as utility companies provide electrical power and water to consumers. Cloud computing provides enormous advantages to small organizations without the resources to purchase, manage, and maintain in-house data centers. Such organizations can dynamically add and delete virtual computer systems from their virtual data centers within public clouds in order to track computational-bandwidth and data-storage needs, rather than purchasing sufficient computer systems within a physical data center to handle peak computational-bandwidth and data-storage demands. Moreover, small organizations can completely avoid the overhead of maintaining and managing physical computer systems, including hiring and periodically retraining information-technology specialists and continuously paying for operating-system and database-management-system upgrades. Furthermore, cloud-computing interfaces allow for easy and straightforward configuration of virtual computing facilities, flexibility in the types of applications and operating systems that can be configured, and other functionalities that are useful even for owners and administrators of private cloud-computing facilities used by a single organization.

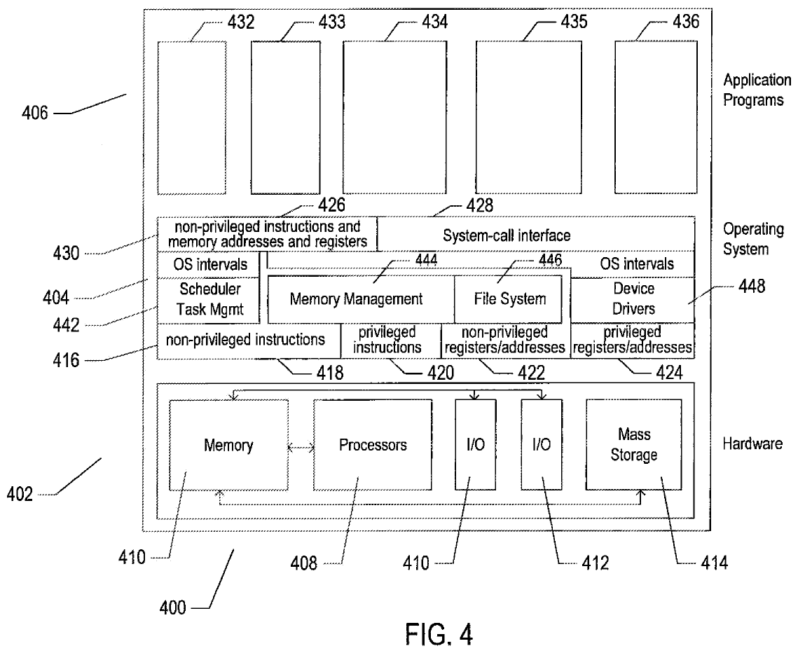

FIG. 4 illustrates generalized hardware and software components of a general-purpose computer system, such as a general-purpose computer system having an architecture similar to that shown in FIG. 1. The computer system 400 is often considered to include three fundamental layers: (1) a hardware layer or level 402: (2) an operating-system layer or level 404; and (3) an application-program layer or level 406. The hardware layer 402 includes one or more processors 408, system memory 410, various different types of input-output (“I/O”) devices 410 and 412, and mass-storage devices 414. Of course, the hardware level also includes many other components, including power supplies, internal communications links and busses, specialized integrated circuits, many different types of processor-controlled or microprocessor-controlled peripheral devices and controllers, and many other components. The operating system 404 interfaces to the hardware level 402 through a low-level operating system and hardware interface 416 generally comprising a set of non-privileged computer instructions 418, a set of privileged computer instructions 420, a set of non-privileged registers and memory addresses 422, and a set of privileged registers and memory addresses 424. In general, the operating system exposes non-privileged instructions, non-privileged registers, and non-privileged memory addresses 426 and a system-call interface 428 as an operating-system interface 430 to application programs 432-436 that execute within an execution environment provided to the application programs by the operating system. The operating system, alone, accesses the privileged instructions, privileged registers, and privileged memory addresses. By reserving access to privileged instructions, privileged registers, and privileged memory addresses, the operating system can ensure that application programs and other higher-level computational entities cannot interfere with one another's execution and cannot change the overall state of the computer system in ways that could deleteriously impact system operation. The operating system includes many internal components and modules, including a scheduler 442, memory management 444, a file system 446, device drivers 448, and many other components and modules. To a certain degree, modern operating systems provide numerous levels of abstraction above the hardware level, including virtual memory, which provides to each application program and other computational entities a separate, large, linear memory-address space that is mapped by the operating system to various electronic memories and mass-storage devices. The scheduler orchestrates interleaved execution of various different application programs and higher-level computational entities, providing to each application program a virtual, stand-alone system devoted entirely to the application program. From the application program's standpoint, the application program executes continuously without concern for the need to share processor resources and other system resources with other application programs and higher-level computational entities. The device drivers abstract details of hardware-component operation, allowing application programs to employ the system-call interface for transmitting and receiving data to and from communications networks, mass-storage devices, and other I/O devices and subsystems. The file system 436 facilitates abstraction of mass-storage-device and memory resources as a high-level, easy-to-access, file-system interface. Thus, the development and evolution of the operating system has resulted in the generation of a type of multi-faceted virtual execution environment for application programs and other higher-level computational entities.

While the execution environments provided by operating systems have proved to be an enormously successful level of abstraction within computer systems, the operating-system-provided level of abstraction is nonetheless associated with difficulties and challenges for developers and users of application programs and other higher-level computational entities. One difficulty arises from the fact that there are many different operating systems that run within various different types of computer hardware. In many cases, popular application programs and computational systems are developed to run on only a subset of the available operating systems and can therefore be executed within only a subset of the various different types of computer systems on which the operating systems are designed to run. Often, even when an application program or other computational system is ported to additional operating systems, the application program or other computational system can nonetheless run more efficiently on the operating systems for which the application program or other computational system was originally targeted. Another difficulty arises from the increasingly distributed nature of computer systems. Although distributed operating systems are the subject of considerable research and development efforts, many of the popular operating systems are designed primarily for execution on a single computer system. In many cases, it is difficult to move application programs, in real time, between the different computer systems of a distributed computer system for high-availability, fault-tolerance, and load-balancing purposes. The problems are even greater in heterogeneous distributed computer systems which include different types of hardware and devices running different types of operating systems. Operating systems continue to evolve, as a result of which certain older application programs and other computational entities may be incompatible with more recent versions of operating systems for which they are targeted, creating compatibility issues that are particularly difficult to manage in large distributed systems.

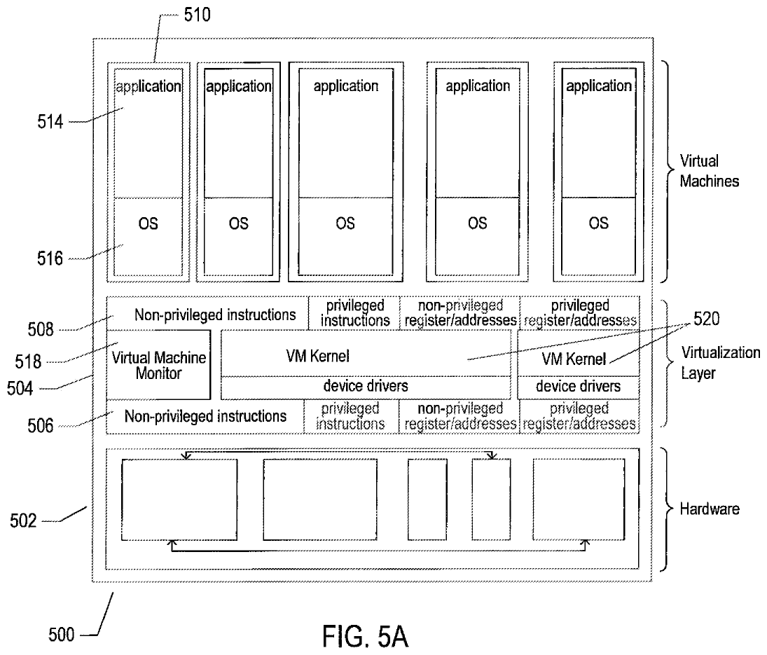

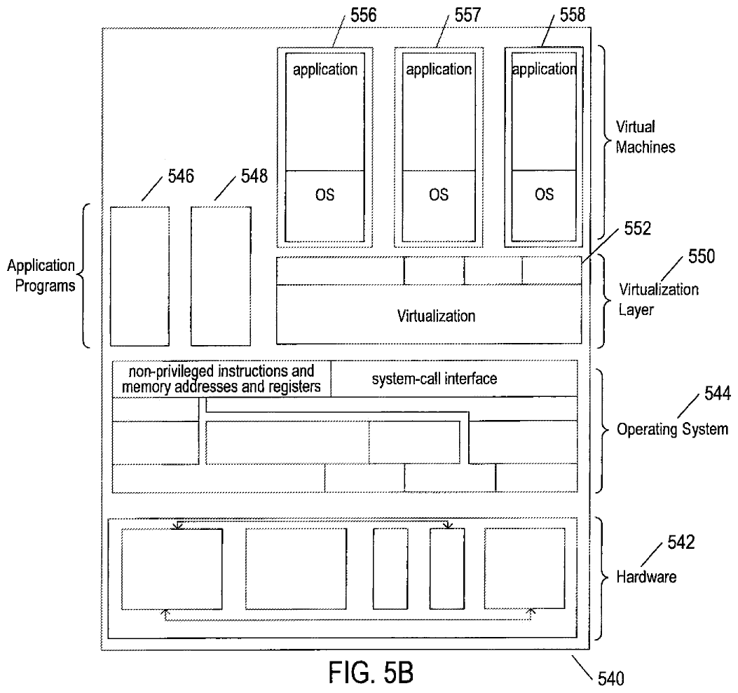

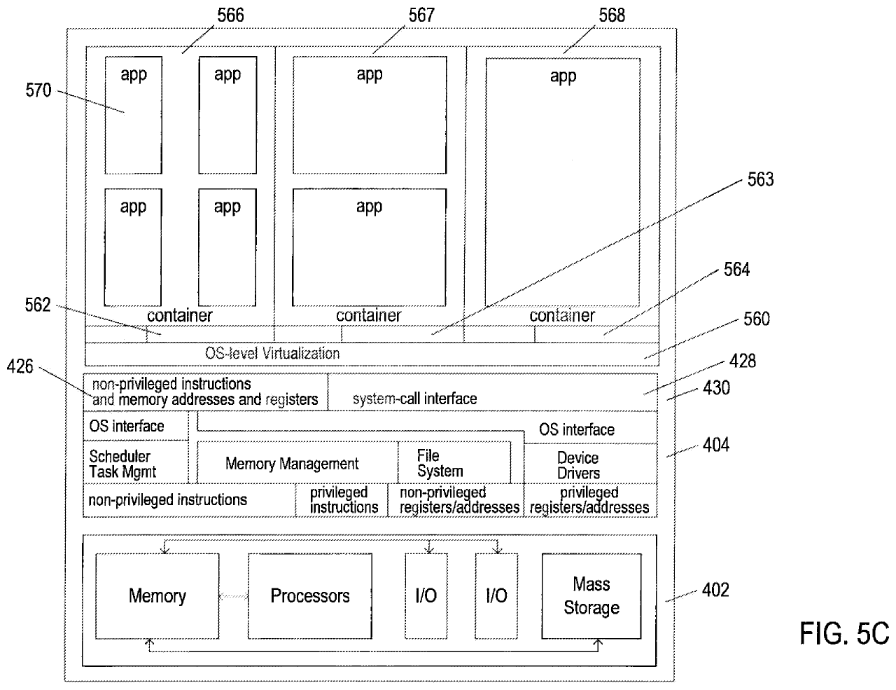

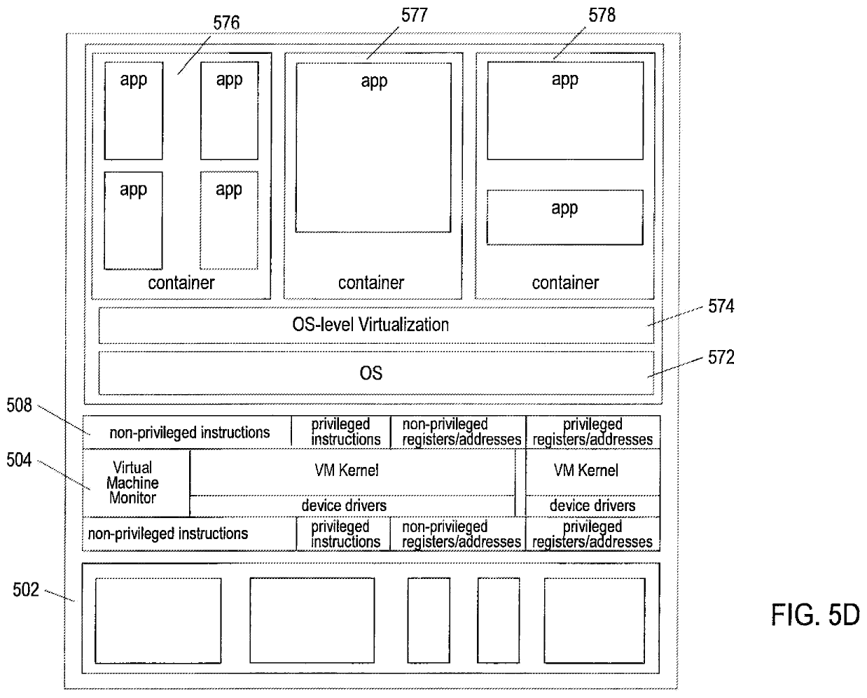

For all of these reasons, a higher level of abstraction, referred to as the “virtual machine,” has been developed and evolved to further abstract computer hardware in order to address many difficulties and challenges associated with traditional computing systems, including the compatibility issues discussed above. FIGS. 5A-D illustrate several types of virtual machine and virtual-machine execution environments. FIGS. 5A-B use the same illustration conventions as used in FIG. 4. FIG. 5A shows a first type of virtualization. The computer system 500 in FIG. 5A includes the same hardware layer 502 as the hardware layer 402 shown in FIG. 4. However, rather than providing an operating system layer directly above the hardware layer, as in FIG. 4, the virtualized computing environment illustrated in FIG. 5A features a virtualization layer 504 that interfaces through a virtualization-layer/hardware-layer interface 506, equivalent to interface 416 in FIG. 4, to the hardware. The virtualization layer provides a hardware-like interface 508 to a number of virtual machines, such as virtual machine 510, executing above the virtualization layer in a virtual-machine layer 512. Each virtual machine includes one or more application programs or other higher-level computational entities packaged together with an operating system, referred to as a “guest operating system,” such as application 514 and guest operating system 516 packaged together within virtual machine 510. Each virtual machine is thus equivalent to the operating-system layer 404 and application-program layer 406 in the general-purpose computer system shown in FIG. 4. Each guest operating system within a virtual machine interfaces to the virtualization-layer interface 508 rather than to the actual hardware interface 506. The virtualization layer partitions hardware resources into abstract virtual-hardware layers to which each guest operating system within a virtual machine interfaces. The guest operating systems within the virtual machines, in general, are unaware of the virtualization layer and operate as if they were directly accessing a true hardware interface. The virtualization layer ensures that each of the virtual machines currently executing within the virtual environment receive a fair allocation of underlying hardware resources and that all virtual machines receive sufficient resources to progress in execution. The virtualization-layer interface 508 may differ for different guest operating systems. For example, the virtualization layer is generally able to provide virtual hardware interfaces for a variety of different types of computer hardware. This allows, as one example, a virtual machine that includes a guest operating system designed for a particular computer architecture to run on hardware of a different architecture. The number of virtual machines need not be equal to the number of physical processors or even a multiple of the number of processors.

The virtualization layer includes a virtual-machine-monitor module 518 (“VMM”) that virtualizes physical processors in the hardware layer to create virtual processors on which each of the virtual machines executes. For execution efficiency, the virtualization layer attempts to allow virtual machines to directly execute non-privileged instructions and to directly access non-privileged registers and memory. However, when the guest operating system within a virtual machine accesses virtual privileged instructions, virtual privileged registers, and virtual privileged memory through the virtualization-layer interface 508, the accesses result in execution of virtualization-layer code to simulate or emulate the privileged resources. The virtualization layer additionally includes a kernel module 520 that manages memory, communications, and data-storage machine resources on behalf of executing virtual machines (“VM kernel”). The VM kernel, for example, maintains shadow page tables on each virtual machine so that hardware-level virtual-memory facilities can be used to process memory accesses. The VM kernel additionally includes routines that implement virtual communications and data-storage devices as well as device drivers that directly control the operation of underlying hardware communications and data-storage devices. Similarly, the VM kernel virtualizes various other types of I/O devices, including keyboards, optical-disk drives, and other such devices. The virtualization layer essentially schedules execution of virtual machines much like an operating system schedules execution of application programs, so that the virtual machines each execute within a complete and fully functional virtual hardware layer.

FIG. 5B illustrates a second type of virtualization. In Figure SB, the computer system 540 includes the same hardware layer 542 and software layer 544 as the hardware layer 402 shown in FIG. 4. Several application programs 546 and 548 are shown running in the execution environment provided by the operating system. In addition, a virtualization layer 550 is also provided, in computer 540, but, unlike the virtualization layer 504 discussed with reference to FIG. 5A, virtualization layer 550 is layered above the operating system 544, referred to as the “host OS,” and uses the operating system interface to access operating-system-provided functionality as well as the hardware. The virtualization layer 550 comprises primarily a VMM and a hardware-like interface 552, similar to hardware-like interface 508 in FIG. 5A. The virtualization-layer/hardware-layer interface 552, equivalent to interface 416 in FIG. 4, provides an execution environment for a number of virtual machines 556-558, each including one or more application programs or other higher-level computational entities packaged together with a guest operating system.

While the traditional virtual-machine-based virtualization layers, described with reference to FIGS. 5A-B, have enjoyed widespread adoption and use in a variety of different environments, from personal computers to enormous distributed computer systems, traditional virtualization technologies are associated with computational overheads. While these computational overheads have been steadily decreased, over the years, and often represent ten percent or less of the total computational bandwidth consumed by an application running in a virtualized environment, traditional virtualization technologies nonetheless involve computational costs in return for the power and flexibility that they provide. Another approach to virtualization is referred to as operating-system-level virtualization (“OSL virtualization”). FIG. 5C illustrates the OSL-virtualization approach. In FIG. 5C, as in previously discussed FIG. 4, an operating system 404 runs above the hardware 402 of a host computer. The operating system provides an interface for higher-level computational entities, the interface including a system-call interface 428 and exposure to the non-privileged instructions and memory addresses and registers 426 of the hardware layer 402. However, unlike in FIG. 5A, rather than applications running directly above the operating system, OSL virtualization involves an OS-level virtualization layer 560 that provides an operating-system interface 562-564 to each of one or more containers 566-568. The containers, in turn, provide an execution environment for one or more applications, such as application 570 running within the execution environment provided by container 566. The container can be thought of as a partition of the resources generally available to higher-level computational entities through the operating system interface 430. While a traditional virtualization layer can simulate the hardware interface expected by any of many different operating systems, OSL virtualization essentially provides a secure partition of the execution environment provided by a particular operating system. As one example, OSL virtualization provides a file system to each container, but the file system provided to the container is essentially a view of a partition of the general file system provided by the underlying operating system. In essence. OSL virtualization uses operating-system features, such as namespace support, to isolate each container from the remaining containers so that the applications executing within the execution environment provided by a container are isolated from applications executing within the execution environments provided by all other containers. As a result, a container can be booted up much faster than a virtual machine, since the container uses operating-system-kernel features that are already available within the host computer. Furthermore, the containers share computational bandwidth, memory, network bandwidth, and other computational resources provided by the operating system, without resource overhead allocated to virtual machines and virtualization layers. Again, however, OSL virtualization does not provide many desirable features of traditional virtualization. As mentioned above. OSL virtualization does not provide a way to run different types of operating systems for different groups of containers within the same host system, nor does OSL-virtualization provide for live migration of containers between host computers, as does traditional virtualization technologies.

Figure SD illustrates an approach to combining the power and flexibility of traditional virtualization with the advantages of OSL virtualization. FIG. 5D shows a host computer similar to that shown in FIG. 5A, discussed above. The host computer includes a hardware layer 502 and a virtualization layer 504 that provides a simulated hardware interface 508 to an operating system 572. Unlike in FIG. 5A, the operating system interfaces to an OSL-virtualization layer 574 that provides container execution environments 576-578 to multiple application programs. Running containers above a guest operating system within a virtualized host computer provides many of the advantages of traditional virtualization and OSL virtualization. Containers can be quickly booted in order to provide additional execution environments and associated resources to new applications. The resources available to the guest operating system are efficiently partitioned among the containers provided by the OSL-virtualization layer 574. Many of the powerful and flexible features of the traditional virtualization technology can be applied to containers running above guest operating systems including live migration from one host computer to another, various types of high-availability and distributed resource sharing, and other such features. Containers provide share-based allocation of computational resources to groups of applications with guaranteed isolation of applications in one container from applications in the remaining containers executing above a guest operating system. Moreover, resource allocation can be modified at run time between containers. The traditional virtualization layer provides flexible and easy scaling and a simple approach to operating-system upgrades and patches. Thus, the use of OSL virtualization above traditional virtualization, as illustrated in Figure SD, provides much of the advantages of both a traditional virtualization layer and the advantages of OSL virtualization. Note that, although only a single guest operating system and OSL virtualization layer as shown in FIG. 5D, a single virtualized host system can run multiple different guest operating systems within multiple virtual machines, each of which supports one or more containers.

### Currently Disclosed Methods and Subsystems

FIG. 6 illustrates a communications protocol stack. As mentioned above, communications protocols are generally layered above one another to provide a variety of different communication services. The lowest level of the communications-protocol stack is often considered to be the hardware layer, L1, that includes communications hardware in each communicating computer and the data-transfer medium 602 through which data is transferred by the communications hardware. The communications hardware can be generally considered to include I/O devices, such as I/O devices 410 or 412 in FIG. 4, discussed above. One such device is referred to as a network-interface controller (“NIC”). The operating system (404 in FIG. 4) generally implements many of the higher-level protocols, with the highest-level protocols in certain communications-protocol stacks implemented by application programs or other executables that execute in execution environments provided by the operating system.

FIG. 6 is vertically divided by a dashed line 604. The communications-protocol-stack levels to the left of this dashed line represent the communications-protocol stack within a sending computer and the communications-protocol-stack levels to the right of this dashed line represent the communications-protocol stack within a receiving computer. The communications-protocol stacks for the sending and receiving computers mirror one another, including the same sequence of levels and associated communications protocols. The data 606 to be transferred from the sender to the receiver is input to an executable that implements the highest-level communications protocol 608 of the communications-protocol stack of the sending computer. The data is wrapped, as the data payload, within a communications-protocol wrapper 610. The communications-protocol wrapper 612 often consists of a header, preceding the data payload, which contains various types of data needed by the communications protocol to provide the communications services associated with the communications protocol. In certain cases, the communications-protocol wrapper may also include a footer that follows the data payload within the packet. The executable implementing the highest-level communications protocol 608 then outputs the communications-protocol packet 610 for input to the next-lowest communications-protocol level 614. The horizontal arrows 616-619 are used indicate that, during reception of the data on the receiving computer, the communications-protocol packet 610 output by communications-protocol layer 608 is input to the highest-level communications-protocol layer 620 in the receiving computer, which unwraps the communications-protocol packet 610 in order to output the data payload 622 initially input 606 to the highest-communications-protocol layer 608 in the sending computer. In essence, each communications-protocol layer in the sending computer transmits a communications-protocol packet for that layer to the corresponding communications-protocol layer in the receiving computer. As the data payload and communications-protocol wrappers are transferred downward through the protocol stack, each communications-protocol layer adds its own wrapper. The final packet 624 physically transmitted through the communications medium 602 includes nested communications-protocol wrappers for all of the communications-protocol levels in the communications-protocol stack.

There are a large number of different types of communications protocols and communications-protocol stacks and a large number of different types of communications services provided by the communications-protocol levels within communications-protocol stacks. Currently disclosed communications protocols provide reliable multi-packet message transmission. They may comprise separate communications-protocol levels within a communications stack or may be incorporated within a particular communications-protocol level within a communications stack. Depending on the particular communications-protocol stack in which the currently disclosed communications protocols are included, the currently disclosed communications protocols may occur at various different levels within different communications-protocol stacks.

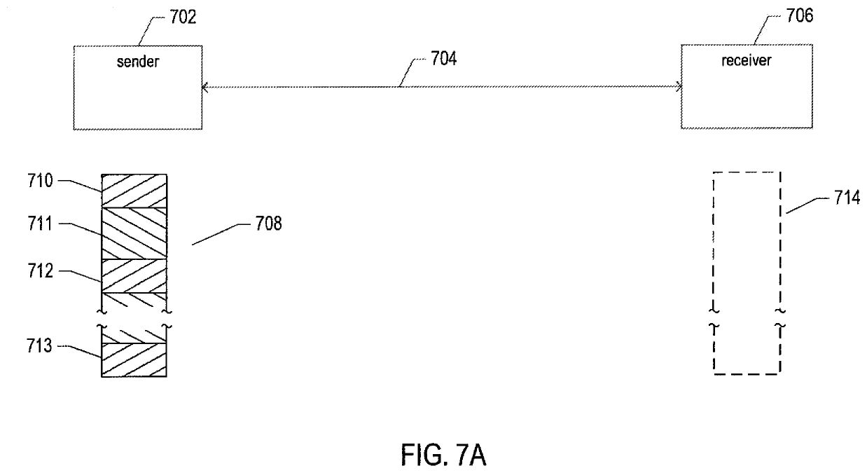

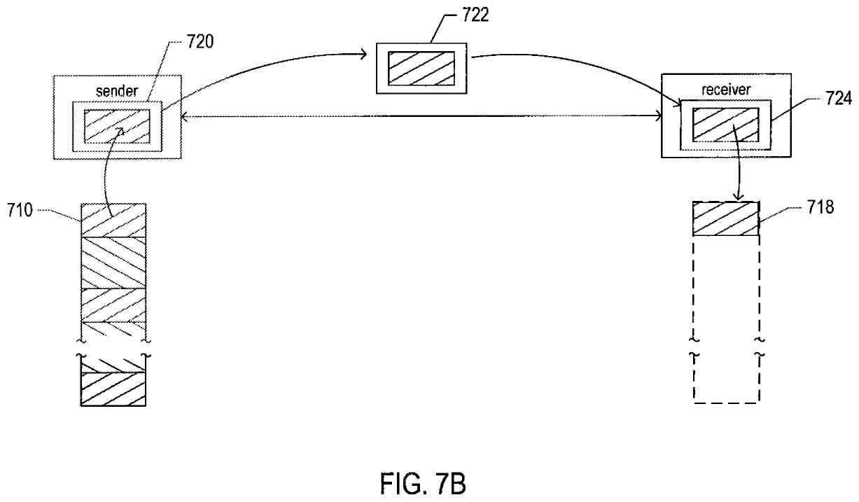

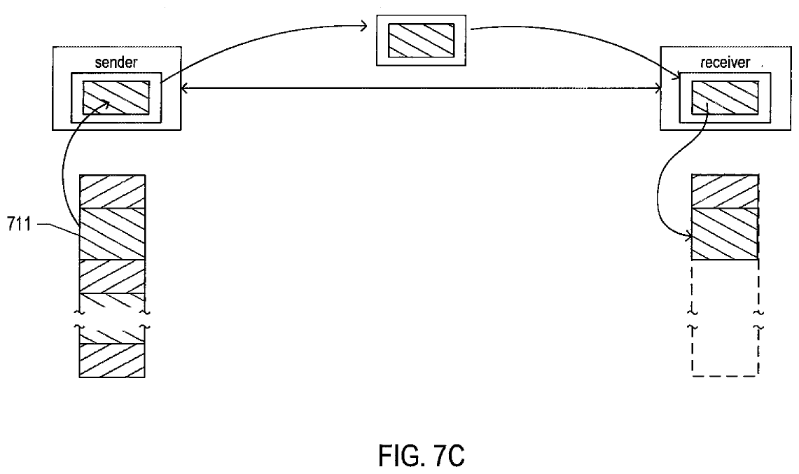

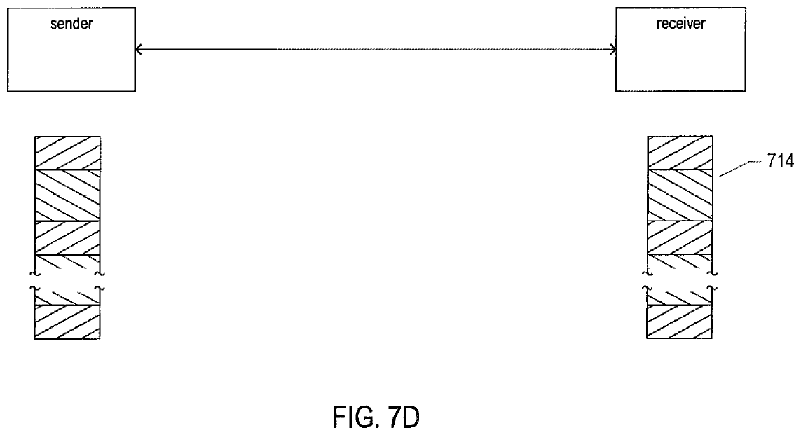

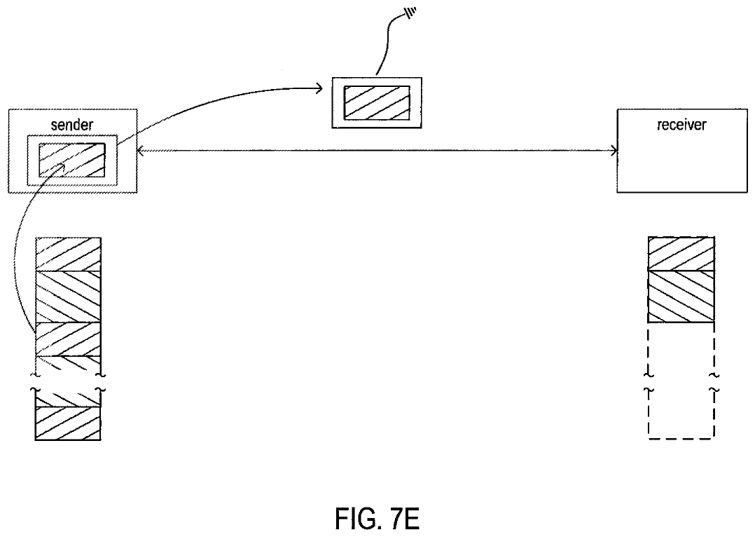

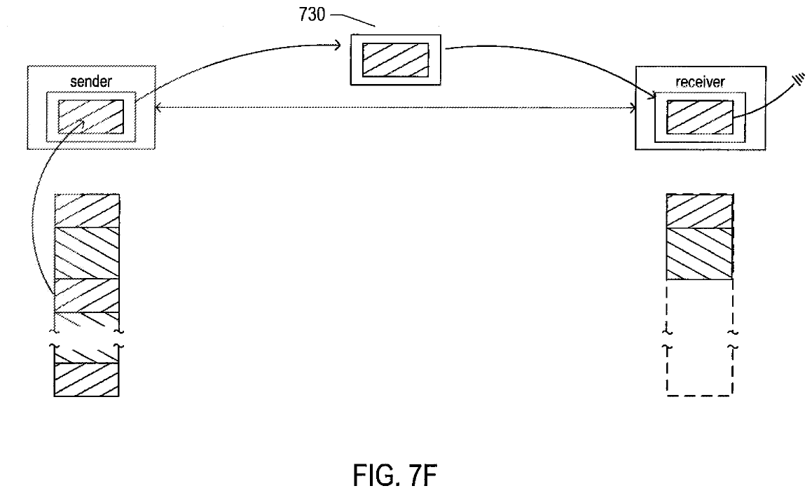

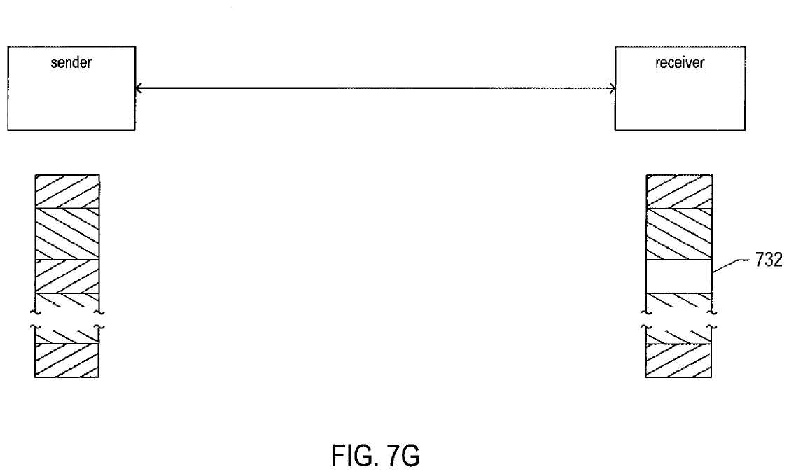

FIGS. 7A-G illustrate multi-packet message transmission. As shown in FIG. 7A, a sending computer 702 is connected by electronic communications 704 to a receiver computer 706. Although the electronic communications 704 is shown as a double-headed arrow, actual hardware and communications media involved in communications between two computer systems may be quite complex and involve many different point-to-point communications media and many different routers, bridges, and other communications devices and computer systems. The sender computer 702 needs to transmit a message, or data, 708 to the receiver computer 706. The message 708 has been partitioned into multiple packets 710-713 that will each be separately and successively transmitted to the receiver computer. The receiver computer will assemble the received packets into a complete message, with the dashed-line rectangle 714 indicating the memory or mass-storage in which the message will be assembled.

FIG. 7B shows the first packet 710 being transmitted to the receiver and placed in memory by the receiver. The packet is encapsulated into multiple layers of protocol wrapping 720, output by the sending computer to the communications media 722, and received by the receiver computer 724, after which the receiving computer extracts the data payload and stores it in memory 718. FIG. 7C similarly shows transmission of the second packet 711. As shown in FIG. 7D, when all the packets have been successfully transmitted by the sending computer to the receiving computer, the multi-packet message has been assembled and stored in memory 714 by the receiving computer. Were packet transmission 100% reliable, then the time taken to transfer message 708 from the sending computer to the receiving computer would be equal to a fraction of the time needed for processing the multiple packets and outputting them to the I/O device, the actual transmission time through the communications media, and the time needed for receiving and processing the multiple packets and storing them in memory by the receiving computer. It would be a fraction of this total time since packet processing by the sending and receiving computers and data transmission may overlap substantially during transmission of a multi-packet message.

Unfortunately, packet transmission is not 100% reliable. As shown in FIG. 7E, a packet output by the sending computer's I/O device may fail to be received by the receiver, for many different reasons. The packet may be corrupted and lost by the various computer systems and devices along the transmission path, sufficiently corrupted during transmission that it cannot be received by the FO device within the receiving computer, or lost due to communications-media failures or failures of the various computer systems and devices along the transmission path. As shown in FIG. 7D, a transmitted packet 730 may be received by the receiving computer, but may be rejected by the receiving computer for various different reasons. The packet may be corrupted during transmission, and unrecoverable corruptions may be detected via error-detection encoding provided by a communications-protocol level, causing the receiving computer to reject the packet. The packet may have been received out-of-order, ahead of a previously transmitted packet that was delayed due to various transmission problems, in which case the receiving computer may drop the packet, depending on the particular communications-protocol stack employed by the receiving computer. As a result, as shown in FIG. 7G, once transmission of the multi-packet message has been completed by the sending computer, the receiving computer will have failed to assemble a complete multi-packet message, but will instead have assembled an incomplete message with missing packets, such as missing packet 732.

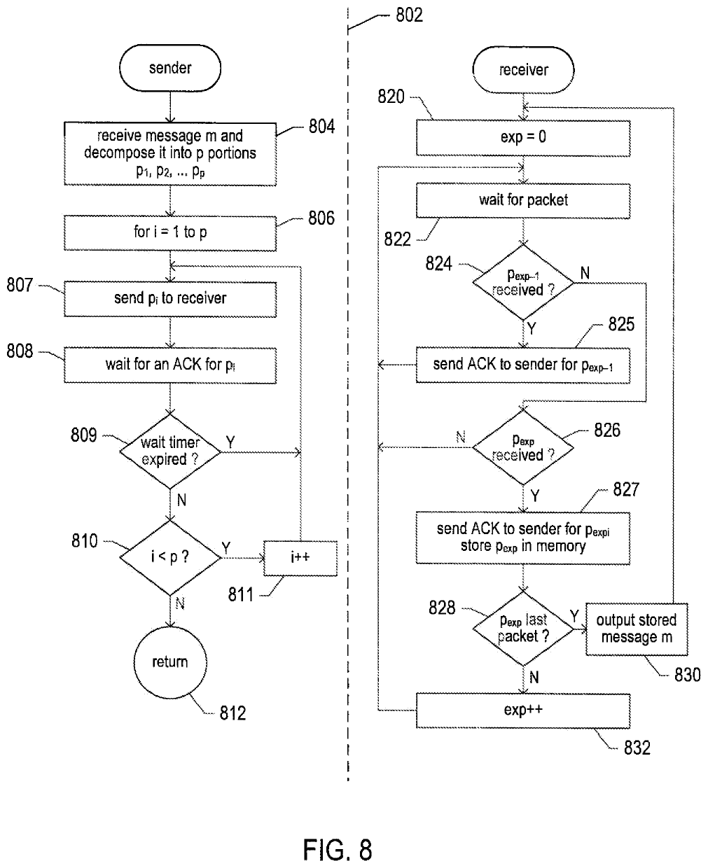

FIG. 8 illustrates one communications-protocol approach to increasing the reliability of multi-packet-message transmission in view of the unreliability of packet transmission. A dashed line 802 divides FIG. 8 into a sender portion and a receiver portion. The sender, in step 804, receives a message m for transmission and decomposes it into P partitions, or packets. Then, in the for-loop of steps 806-811, the sender transmits the P packets to the receiver. Of course, each packet includes a communications-protocol wrapping around the data payload corresponding to a partition of the original message. In each iteration of the for-loop of steps 806-811, the sender sends the next packet to the receiver, in step 807. The sender then waits, in step 808, for the receiver to return an acknowledgment, or ACK, indicating that the packet was received. If a wait timer expired as a result of failure by the receiver to return an ACK message, as determined in step 809, control flows back to step 807 where the sender again tries to send the next packet to the receiver. Otherwise, control flows to step 810, where the sender determines whether or not all the packets have been sent. If not, the loop variable i is incremented, in step 811, and control flows back to step 807. Otherwise, the message has been successfully transmitted and the sender routine completes 812.

The receiver sets a local variable exp to 0, in step 820. Then, in step 822, the receiver waits for the arrival of a packet. If a previously received packet is again received, as determined in step 824, the receiver resends an ACK for that packet to the sender, in step 825, following which control returns to step 822. Otherwise, when the receiver did not receive the expected packet in the packet sequence, as determined in step 826, the received packet is ignored and control returns to step 822. Otherwise, the receiver sends an ACK for the expected packet to the sender and stores the received packet in memory, in step 827. When the last packet in the sequence has been received, as determined in step 828, the receiver outputs the received message m to a consumer of the message, in step 830, and control then returns to step 820. Otherwise, local variable exp is incremented, in step 832, and control returns to step 822.

The communications protocol illustrated in FIG. 8 is incomplete, since, as one example, were the transmission medium to fail, the sender would simply spin in the for-loop of steps 806-811 indefinitely. As discussed later, this problem can be addressed by detecting more than a threshold number of failures for a given packet and returning a failure indication indicating that the message could not be sent. There are additional problems with this simplistic protocol. However, the biggest problem is that the temporal latency associated with sending a multi-packet message is much higher than the theoretical latency for a 100% reliable packet-transmission system. For each packet transmitted by the sender, the sender has to wait for the receiver to receive the packet and then transmit an ACK back to the sender, adding multiple delays for generation and transmitting each of the ACK messages. The communications protocol illustrated in FIG. 8 is thus quite inefficient with respect to the temporal latency associated with sending a multi-packet message. It is, however, efficient in the sense that only lost packets need to be retransmitted by the sender.

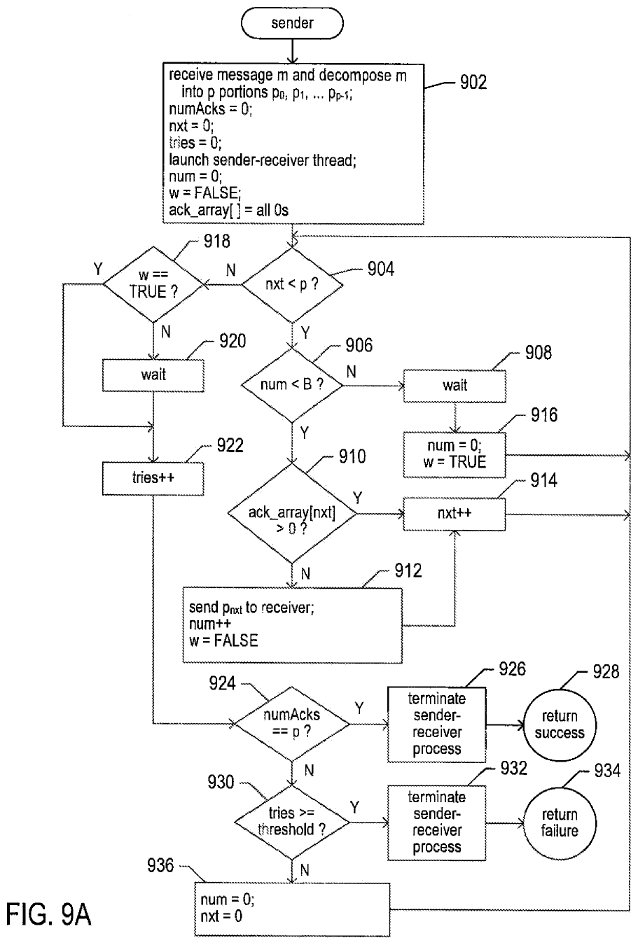

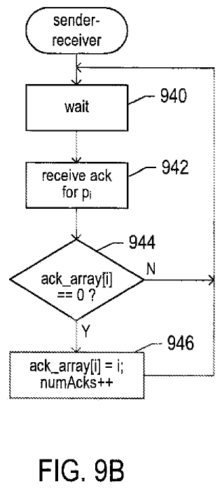

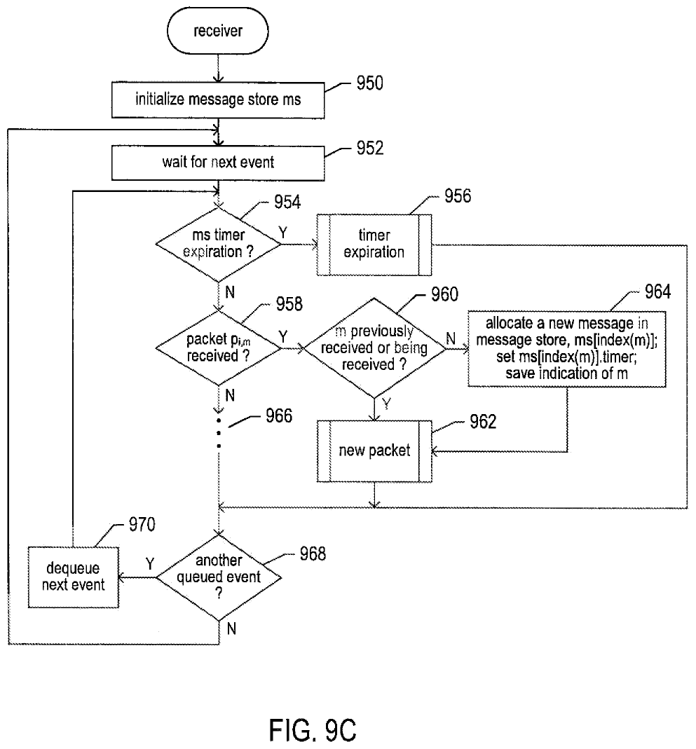

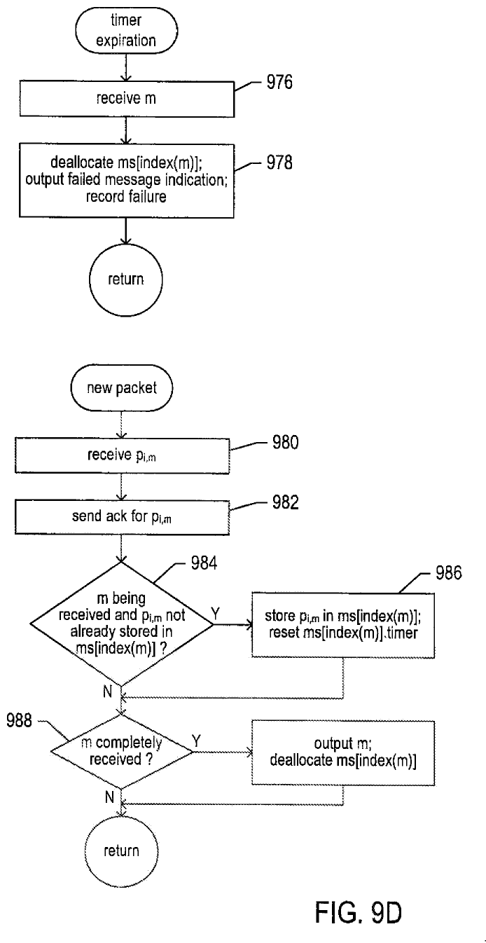

FIGS. 9A-D illustrate an example of an ARQ communications protocol. FIGS. 9A-B illustrate the sender side and FIGS. 9C-D illustrate the receiver side. Of course, in general, both computers in a communicating pair of computers include both sending and receiving functionalities. In step 902 of FIG. 9A, the sender receives a message m and partitions it into P partitions. Global variable numAcks and local variables nxt, num, and tries are initialized to 0. Local variable nxt indicates the next packet to send. Local variable num maintains a count of the number of packets that have been sent during a current loop iteration. Local variable tries maintains a count of the number of packet-sending loop iterations that have been carried out. Local Boolean variable w is initialized to FALSE and indicates whether a waiting period has transpired since completion of a packet-sending-loop iteration. Global variable numAcks maintains a count of the number of packets for which ACK messages have been received. The global array ack_array is initialized to contain all 0 values. A sender-receiver thread is also launched. The sender-receiver thread receives ACK messages from the receiver and records indications of the received ACK messages in the array ack_array and counts the number of packets for which ACK messages have been received in global variable numAcks.

In step 904, the sender checks to see whether all of the packets have been sent. If not, then, in step 906, the sender determines whether or not B packets have been sent prior to waiting, in step 908. If not, then the sender determines, in step 910, whether the packet nxt has been previously transmitted and acknowledged by the receiver. If not, then in step 912, the sender sends the packet nxt to the receiver, increments local variable num, and sets local variable w to FALSE. When packet nxt has been acknowledged, as determined in step 910, or following sending of the packet nxt in step 912, local variable nxt is incremented, in step 914. When, in step 906, it is determined that B packets have been sent prior to waiting, control flows to step 908 where the sender waits briefly before setting local variable num to 0 and local variable w to TRUE, in step 916. Thus, the loop of steps 904 through step 916 iterates through all of the packet numbers, sending those packets for which acknowledgments have not been received from the receiver. After B packets have been transmitted, the sender briefly waits before resuming transmission of packets. When the loop of steps 904 through step 916 has iterated through all of the packet numbers, as determined in step 904, control flows to step 918 where the sender determines whether or not the sender has waited after transmitting the last packet. If not, the sender briefly waits, in step 920. In step 922, the local variable tries is incremented. When all of the packets in the message m have been acknowledged by the receiver, as determined in step 924, the sender terminates the sender-receiver thread, in step 926, and then returns a success indication 928. Otherwise, when the value stored in local variable tries is greater than or equal to a threshold value, as determined in step 930, the sender terminates the sender-receiver thread, in step 932, and then returns a failure indication in step 934. Otherwise, local variables num and nxt are reset to 0, in step 936, and control flows back to step 904 to begin another iteration of the loop of steps 904 through step 916. Thus, the sender determines those packets for which acknowledgments have not been received and attempts to retransmit them in each successive execution of the loop of steps 904 through step 916. After a threshold number of attempts to retransmit unacknowledged packets, the sender returns a failure indication in step 934.

FIG. 9B illustrates the sender-receiver thread launched in step 902 of FIG. 9A. In step 940, the sender-receiver thread waits for a next ACK message. When a next ACK message is received for packet i 942, the sender-receiver thread determines, in step 944, whether the packet i had already been acknowledged. If not, the ACK message is recorded in ack_array and the variable numAcks is incremented in step 946, after which control returns to step 940.

FIG. 9C illustrates the receiver process. In step 950, the receiver initializes a message store ms. In step 952, the receiver waits for a next event to occur. When a next event occurs, the receiver determines, in step 954, whether the event that has occurred is a timer expiration. If so, then a timer-expiration handler is called, in step 956. Otherwise, if the event that has occurred is the reception of a packet pᵢ for message m, as determined in step 958, the receiver determines, in step 960, whether the message m was either already completely received or is currently being received. If so, then a routine “new packet” is called, in step 962, to handle the new packet. Otherwise, in step 964, the receiver allocates space for storing the message in in the message store, sets a timer for the new message, and records the fact that message n is now being received. Ellipsis 966 indicates that other types of events may be handled by the receiver. When there is another queued event to handle, as determined in step 968, that event is dequeued, in step 970, and control returns to step 954 for handling the event. Otherwise, control returns to step 952, where the receiver waits for the occurrence of a next event.

FIG. 9D illustrates the timer-expiration handler and the “new packet” routine. The timer-expiration handler receives an indication of a message n, in step 976, and then, in step 978, deallocates storage for message m, outputs a failure indication, and records failure of the message. The “new packet” routine receives a packet pᵢ for the message m, in step 980 and returns an ACK message to the sender, in step 982. When message m is currently being received and the packet pᵢ has not already been received, as determined in step 984, the packet is stored in the message store and the timer for message m is reset, in step 986. When packet pᵢ is the last packet for message i, as determined in step 988, the receiver outputs message m to a message consumer and removes message m from the message store. Of course, in alternative implementations, the receiver may output a reference to the message and maintain the message in the message store until it is consumed by the consumer. These and other details are not described or illustrated, because FIGS. 9A-D are provided and discussed in order to describe the overall approach of one implementation of the ARQ approach to increasing the reliability of multi-packet-message transmission.

The main feature of the ARQ method that improves the naïve communications protocol discussed above with reference to FIG. 8 is the fact that the sender does not wait for an ACK message after sending each packet, but instead automatically re-transmits packets for which ACK messages have not been received within a relatively short period of time. This slightly increases the chance of unnecessarily retransmitting packets, but greatly decreases the overall temporal latency for multi-packet message transmission.

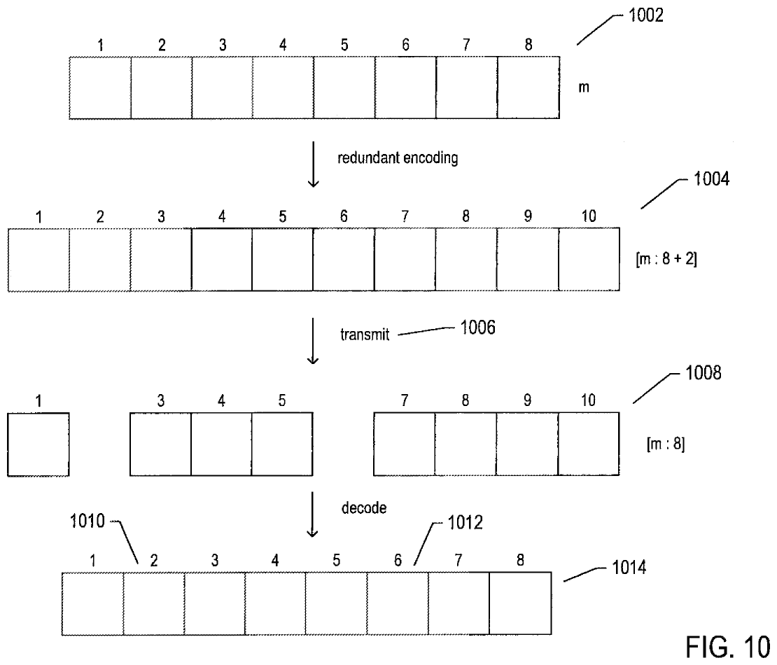

FIG. 10 illustrates encoding of redundant information into a multi-packet message by a sender that allows the receiver of the multi-packet message to automatically recover packets for which transmission has failed. A multi-packet message 1002 is shown at the top of FIG. 10. The multi-packet message includes 8 packets. The sender includes redundant information in an encoding of the message 1004, increasing the number of packets to 10. The encoded multi-packet message is then transmitted 1006 to a receiver, which receives only 8 of the 10 transmitted packets 1008 due to two packet-transmission failures. Nevertheless, because of the redundant information encoded into the encoded multi-packet message 1004, the receiver is able to extract the two missing packets 1010 and 1012 from the eight received encoded packets and construct the original multi-packet message 1014 with 8 packets. There are a variety of different multi-packet encoding schemes. Perhaps the most commonly used encoding scheme is the Reed-Solomon encoding method. In general, the more redundant information encoded into a message, the greater the number of missing packets that can be recovered by the receiver.

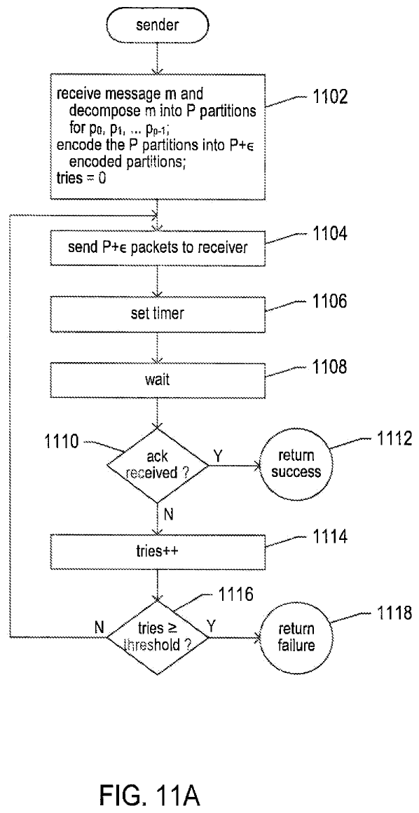

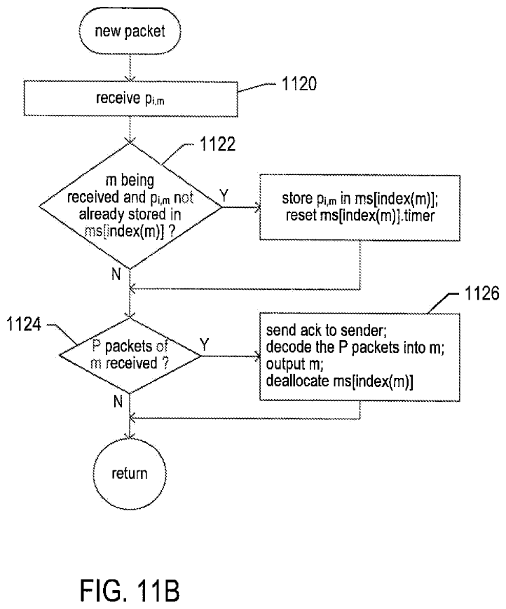

FIGS. 11A-B illustrate an FEC-based communications protocol for increasing the reliability of multi-packet-message transmission. Only the “sender” and “new packet” routines shown in FIGS. 9A-D need be modified in order to implement the FEC-based communications protocol. In step 1102 of the new sender routine, the sender receives a message m and partitions the message into P partitions pᵢ, where i∈[0, P]. The sender then encodes the P partitions into P+ε, partitions and sets the local variable tries to 0. In step 1104, the sender sends P+ε packets to the receiver and then, in step 1106, sets a timer. In step 1108, the sender waits for an ACK message from the receiver. When an ACK message has been received, as determined in step 1110, the sender returns a success indication in step 1112. Otherwise, the wait in step 1108 has timed out, in which case the sender increments the local variable tries, in step 1114, and when the value stored in local variable tries is less than the threshold value, as determined in step 1116, control returns to step 1104 where the sender again tries to send the P+ε partitions of the encoded multi-packet message to the receiver. When the value stored in local variable tries is greater than or equal to a threshold value, the sender returns a failure indication, in step 1118.

FIG. 11B illustrates the new routine “new packet” for the FEC-based communication-protocol implementation. In step 1120, the routine “new packet” receives a packet pᵢ for the message n. When the message no is currently being received and packet pᵢ has not already been stored in the message store, as determined in step 1122, the receiver stores packet pᵢ in the message store and resets the timer for message n. When P of the P+ε packets of the encoded messages have been received, as determined in step 1124, the receiver sends an ACK message to the sender, decodes the P received packets into the message n, outputs the message in, and removes the message m from the message store, in step 1126.

The FEC-based communications protocol illustrated in FIGS. 11A-B, along with FIGS. 9A-D, removes the necessity for the receiver to send ACK messages for individual received packets and for the sender to automatically retransmit packets for which ACK messages have not been received. When the transmission failure rate is low, the receiver is able to decode partially-received multi-packet messages in order to construct packets for which transmission failed. Only in the very infrequent cases of transmission failure is the sender required to attempt to retransmit an encoded multi-packet message. However, these advantages come at the expense of always transmitting redundant information for a multi-packet message. The temporal latency for transmitting multi-packet messages via the FEC-based communications protocol is significantly decreased, but additional communications bandwidth is required for transmission of redundant information, which also slightly increases temporal latencies.

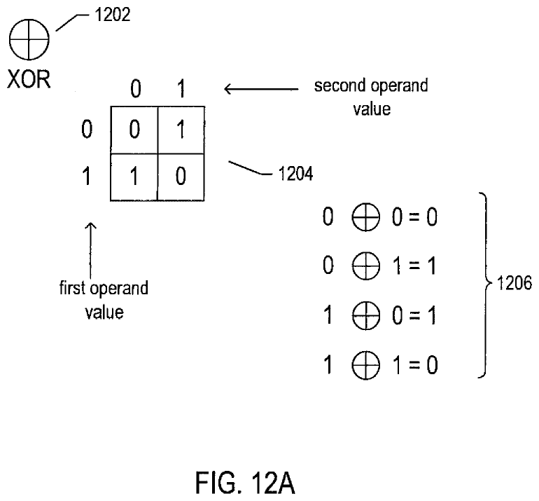

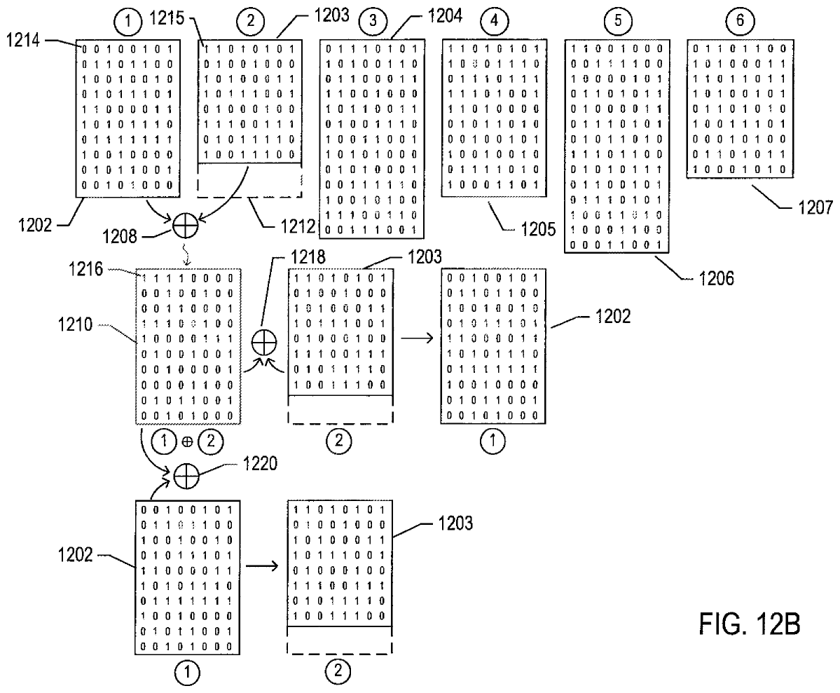

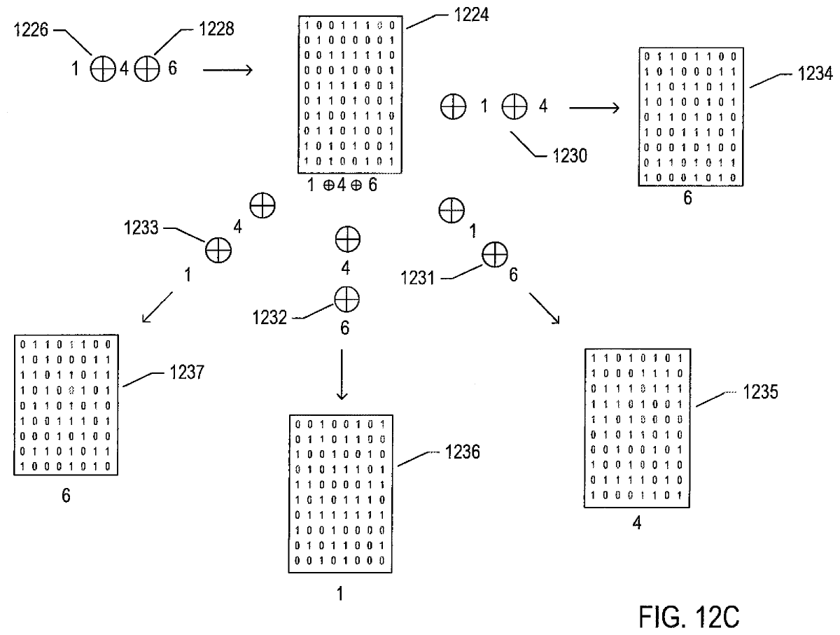

FIGS. 12A-C illustrate XOR-based check packets. FIG. 12A illustrates the XOR operation. The XOR operation is symbolically represented by symbol 1202. An XOR operation can be carried out on two Boolean values, which can each be represented by a single bit, or can be carried out on two strings or streams of Boolean values, such as the digitally-encoded contents of multi-packet-message packets. FIG. 12A shows the truth table 1204 for the XOR operation applied to two Boolean values. The rows of the truth table correspond to the two possible Boolean values of a first operand and the columns of the truth table correspond to the two possible Boolean values of a second operand. The possible operands and resulting values contained in the truth table can be alternatively shown by the four expressions 1206.

FIG. 12B shows a digital encodings of six packets of a multi-packet message along with a check packet generated by a XOR operation on two of the packets of the multi-packet message. The six packets of the multi-packet message 1202-1207 are shown at the top of FIG. 12B. Each packet is labeled with a circled digit indicating the position of the packet in the sequence of packets that together comprise the multi-packet message. The digital encodings are provided to illustrate packet-based XOR operations, but, of course, actual packets contain far more data than the handful of digitally-encoded bytes shown in packets 1202-1207 used as an example multi-packet message in FIG. 12B. A first packet-based XOR operation, represented by symbol 1208, includes the first two packets 1202-1203 as operands and generates a result packet 1210. A packet-based XOR operation logically extends, when the operand packets have different lengths, the shorter of the two operand packets with 0 bits so that both packet operands have the same length. In FIG. 12B, the extension of packet 1203 is indicated by the dashed-line rectangle 1212 appended to packet 1203. The packet-based XOR operation then carries out a bit-by-bit XOR of corresponding bits in the two operand packets to generate the result packet. Thus, for example, the first bit 1214 in packet 1202 is 0 and the second bit 1215 in packet 1203 is 1, so that the first bit in the result packet 1216 is equal to 0⊕1=1, according to the truth table shown in FIG. 12A. It should be noted that extension of packets is reflected in a length field associated with packets, in the implementations discussed below.

The result packet 1210, in the current discussion, may constitute the data payload of a check packet, often referred to simply as a “check” in the discussion below. A check packet has the interesting property that, when the check packet is included as an operand in a subsequent XOR operation with one of the two packets used to generate the check packet, the other packet used to generate the check packet is produced. Thus, the XOR operation 1218 that includes the check packet and the second packet 1203 as operands produces the first packet 1202. Here again, it is assumed that the second packet 1203 is logically extended with 0 bits in order to have the same length as the check packet. Similarly, the XOR operation 1220 that includes the check packet and the first packet 1202 as operands produces the second packet 1203.

As shown in FIG. 12C, this interesting property of check packets extends to check packets produced from more than two packets. In FIG. 12C, a check packet 1224 is produced by a first XOR operation 1226 in which packet 1202 and packet 1205 are operands, and the result packet is then used as an operand in a second XOR operation 1228 that includes packet 1207 as the second operand. The order of the operands in a multiple-XOR operation does not change the result. Check packet 1224 would be produced by any of the following multiple-XOR operations: 1⊕4⊕6, 1⊕6⊕4, 4⊕1⊕6, 4⊕6⊕1, 6⊕4⊕1, and 6⊕1⊕4. When the check packet 1224 is then used as the first operand in various different multiple-XOR operations 1230-1233, the packet left out from the multiple-XOR-operation is produced 1234-1237, respectively. The ordering of the operands in the multiple-XOR operations 1230-1233 is also not important. Furthermore, when the check packet, which can be described as the product of the multiple-XOR-operation 1⊕4⊕6, is included in an additional XOR operation with one of the initial operands used to produce the check packet, a check packet corresponding to the other two initial operands is produced: 16 ⊕4⊕1⊕6⊕4. Again, the order of the operands in these XOR and multiple-XOR-operations is not significant.

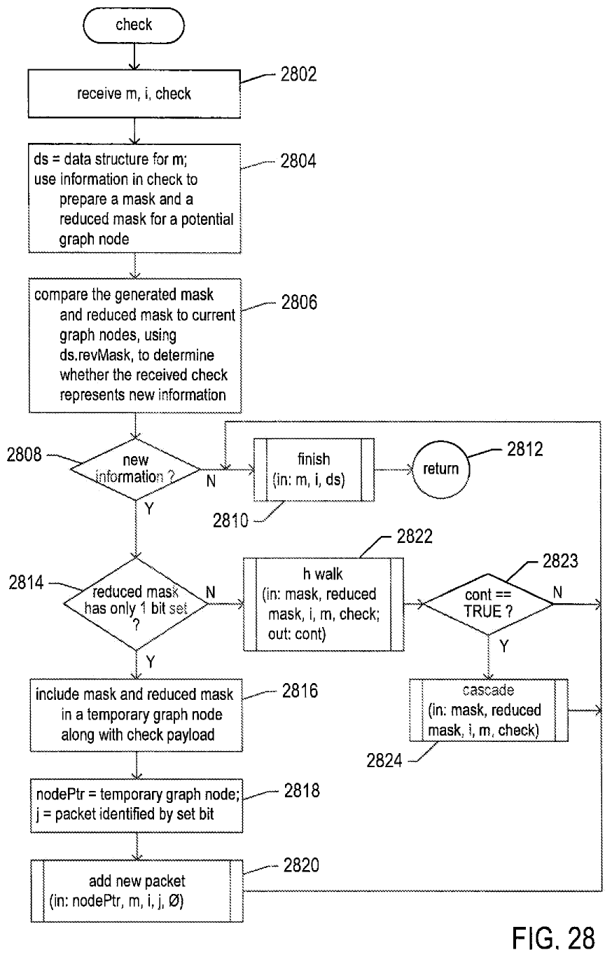

In the currently disclosed communications protocols, check packets are used by a sender to assist a receiver in recovering packets for which transmission initially failed. For example, if the sender has initially transmitted all of the six packets 1202-1207 to the receiver, and the receiver has received all but packet 5 (1206 in FIG. 28), then were the sender to send the check packet 4⊕5⊕6 to the receiver, the receiver could construct the missing packet 5 (1206 in FIG. 12B) by the multiple-XOR-operation check ⊕4⊕6=5. Thus, when a check packet is generated by a multiple-XOR-operation involving n packets of the initially transmitted packets of a multi-packet message, any one of those packets can be recovered using the check packet and n−1 of the initially transmitted packets.

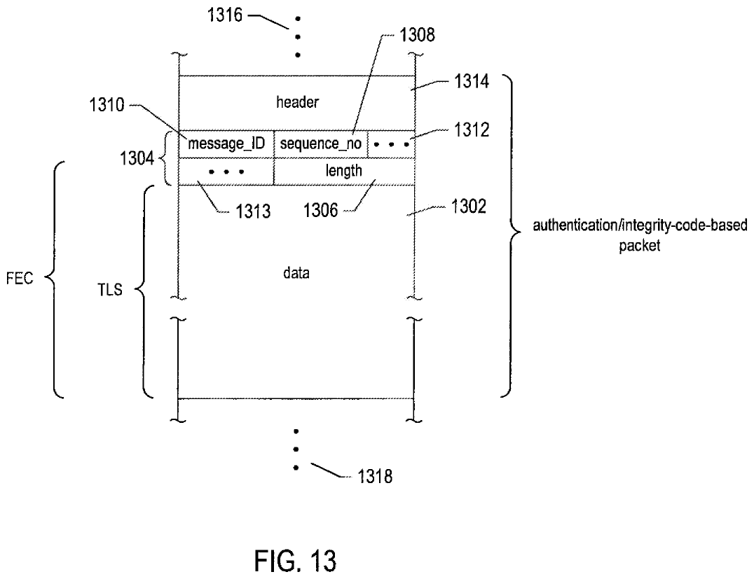

FIG. 13 illustrates a communications-protocol environment in which the currently disclosed communications protocol is incorporated. Data is transmitted via multi-packet messages. The data for a packet 1302, referred to as the “data payload,” is wrapped by multiple lower-level communication-protocol wrappers. A first wrapper includes a packet header 1304 which includes a length indication 1306 that describes the length of the packet header and data payload, a sequence number 1308 that indicates the packet's position in a sequence of packets of the packet, a message identifier 1310, and other information indicated by ellipses 1312-1313. The data payload and packet header 1304 are wrapped within the communications-protocol wrapper for a lower-level communications protocol which includes a header 1314. Ellipses 1316 and 1318 indicate that additional communication-protocol-level wrappers may be present. The currently disclosed communications protocol uses a version of forward-error correction to increase the reliability of multi-packet messages, with the forward-error-correction encompassing a portion of header 1304 (the length field 1306 and, depending on the specific protocols, possibly additional fields) and data payload 1302. The other portion of header 1304, including the sequence-number field 1308, is not included in forward-error-correction. Of course, the division of header information into distinct wrapper layers is somewhat arbitrary. The data payload is encrypted by a higher-level transport-layer-security protocol and the integrity of the packet header 1304 and data payload 1302 are checked and the packet header 1304 and data payload 1302 are authenticated by the lower-level communications protocol that uses the header 1314 as a communications-protocol wrapper. Additional communications services, such as routing, are provided by lower-level protocols. The currently disclosed FEC-based communications protocol may be incorporated within an existing communications-protocol level or may represent a distinct communications-protocol level within a communications-protocol stack. Thus, the FEC-encompassed portion of a data packet includes both data payload and the length field.

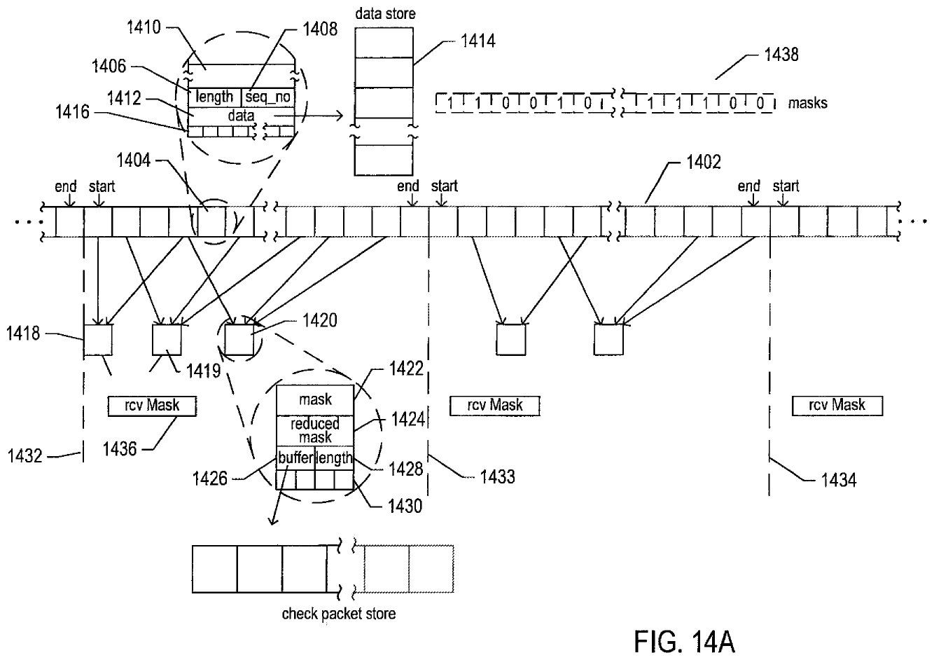

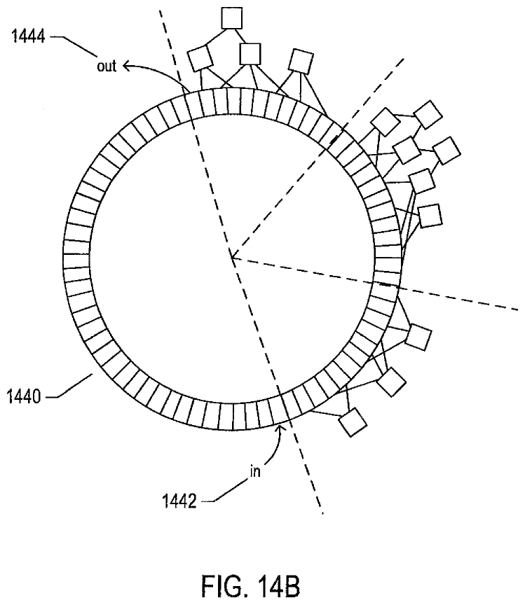

FIGS. 14A-B illustrate a data structure that is used on the receiver side to implement the currently disclosed FEC-based communications protocol. The horizontal band 1402 in FIG. 14A is a sequence of packet data structures corresponding to the packets of a multi-packet message. Each packet data structure, such as packet data structure 1404, includes the length field 1406 and sequence-number field 1408 of a received packet, may include additional fields 1410, and includes a pointer 1412 to the data payload of the packet which is stored in a data store 1414. In certain implementations, the sequence-number field can be omitted, with the index of the packet data structure in an array of packet data structures used as the sequence number for the data packet. In addition, the packet data structure includes a variable number of pointers or references 1416 to certain of the nodes of a check-packet graph, such as graph nodes 1418-1420, when the data packet corresponding to the packet data structure has not been received or revealed. The referenced nodes represent check packets or derived check packets that represent the products of multiple XOR operations of data packets that include the data packet represented by the packet data structure. Once the data packet is received or revealed using other received data packets and one or more check packets and derived check packets, the corresponding packet data structure no longer needs to reference graph nodes. The no-longer needed references can be removed and the formerly directly referenced check packets and indirectly referenced derived check packs can be evaluated for removal when they are no longer directly or indirectly referenced from one or more other packet data structures. Each graph node includes a mask 1422 that is a bitmap representing the data packets used in an XOR operation or multiple-XOR operation to generate the check packet represented by the graph node, a reduced mask 1424, which indicates the XOR combination of unreceived data packets that can be obtained by an XOR or multiple-XOR operation including the check packet represented by the graph node and other already-received data packets, a pointer 1426 to the check-packet payload for the check packet represented b % the graph node, an indication of the length of the check-packet payload 1428, and a variable number of pointers, or references, to higher-level graph nodes 1430. The horizontal band 1402 is partitioned into partitions, as indicated by vertical dashed lines 1432-1434. Thus, in the case of the currently disclosed communications protocol, a multi-packet message is partitioned into multiple partitions, each including multiple packets. Thus, each partition is associated with its own, separate check-packet graph and the mask 1422 and reduced-mask 1424 fields of the graph nodes in a partition refer to the data packets encompassed by the partition. Each partition may be associated with a length indication, in certain implementations. Each partition is also associated with a rcvMask, such as rcvMask 1436, which is a bitmap indicating those data packets of the partition that have already been received. As is shown by mask 1438, the mask 1422 and reduced-mask 1424 fields of the graph nodes and the rcvMask of each partition include a number of bits equal to the number of packets in a partition.

As shown in FIG. 14B, the data structure illustrated in FIG. 14A may be logically circular. The horizontal band 1402 in FIG. 14A can be rendered logically circular 1440 using modulo arithmetic. Circular queues are well-known in computer science. Partitions can be added, beginning with the entry referenced by an in pointer 1442 to increase the number of partitions in a clockwise direction and can be removed, from the entry referenced by an out pointer 1444, in order to decrease the number of partitions. A circular queue allows for convenient continuous addition of queue entries and removal of queue entries in first-in-first-out order. In the current case, as all of the packets in a partition are received, the circular data structure can be rolled forward to remove completed partitions and provide space for packets that will be received for subsequent partitions.

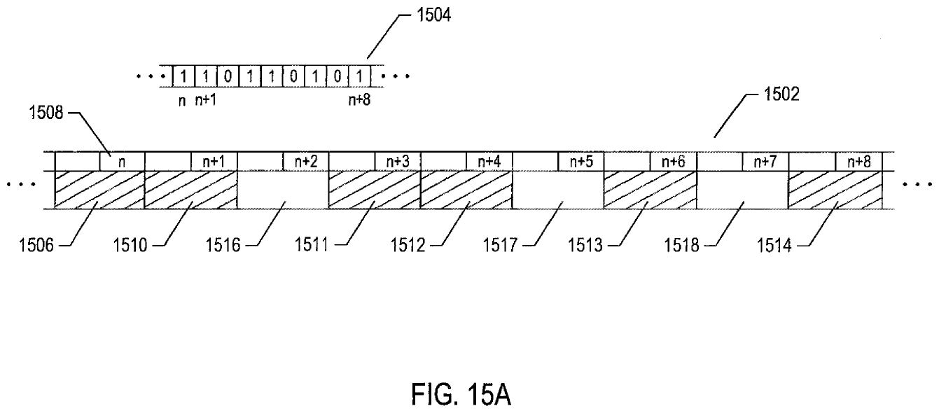

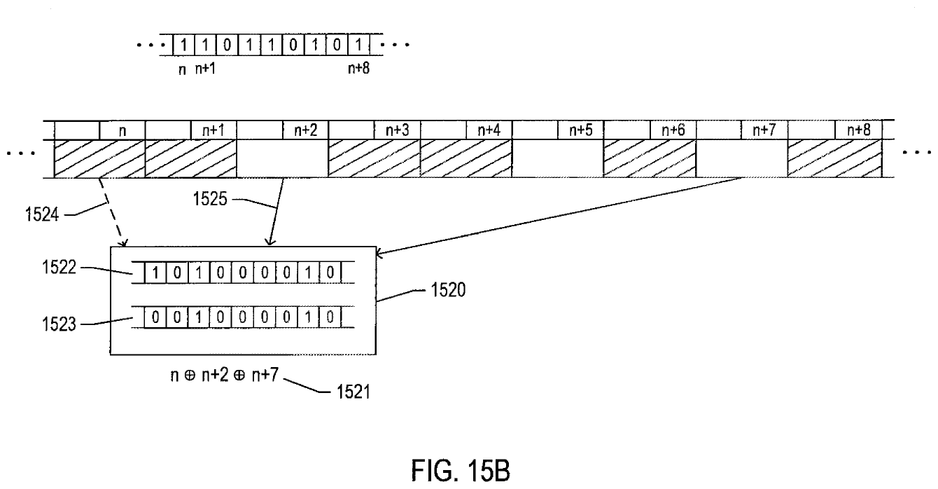

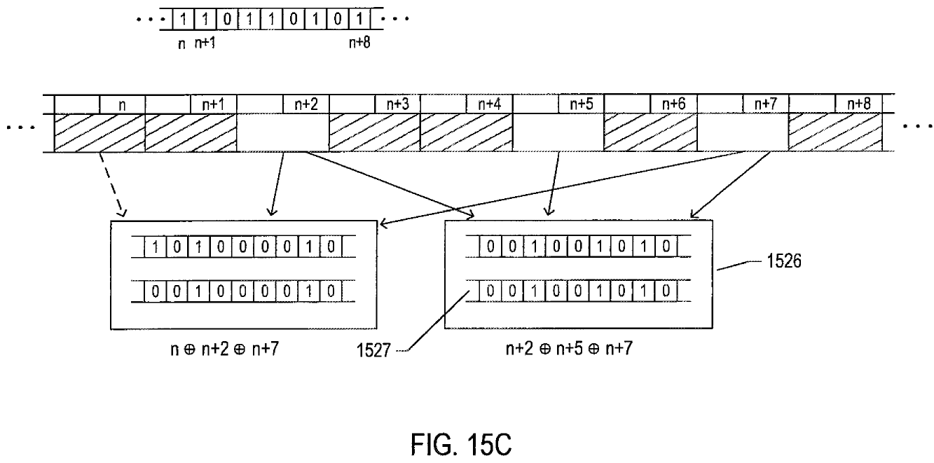

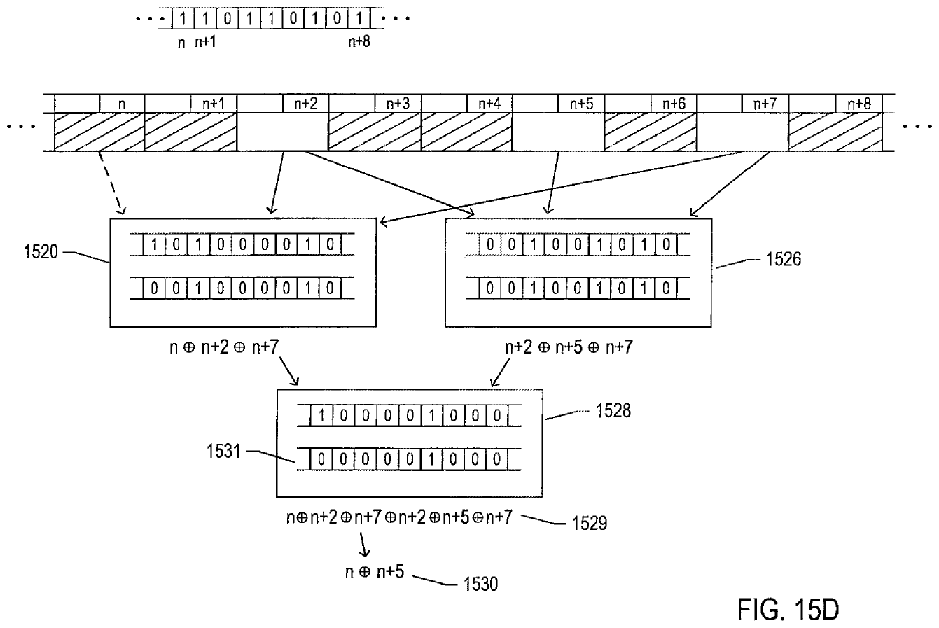

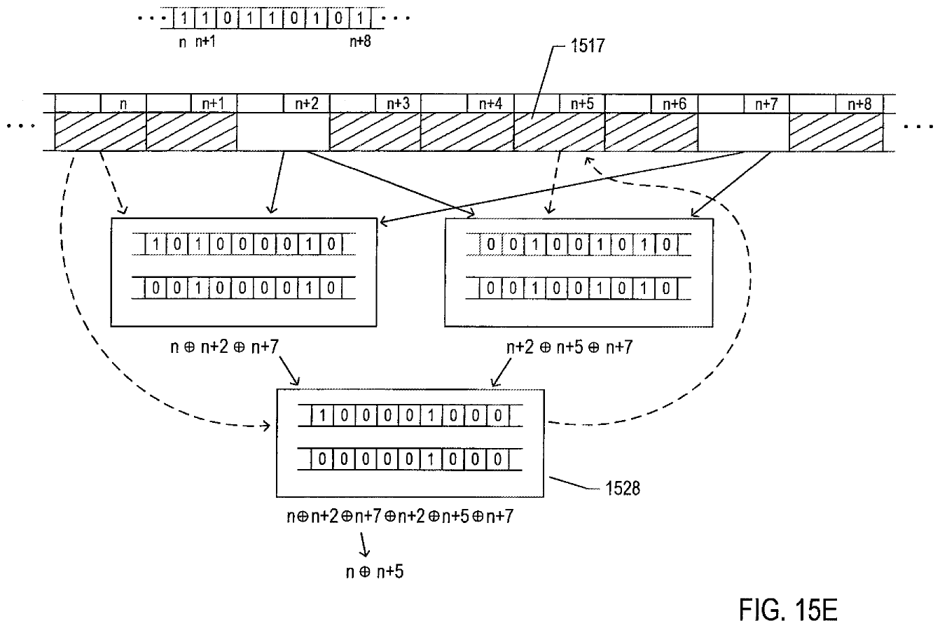

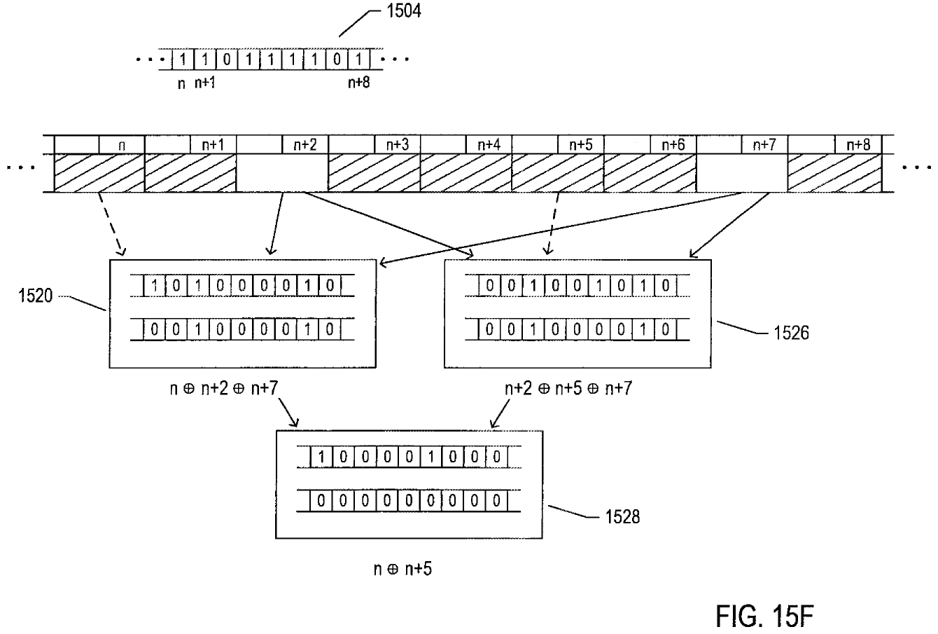

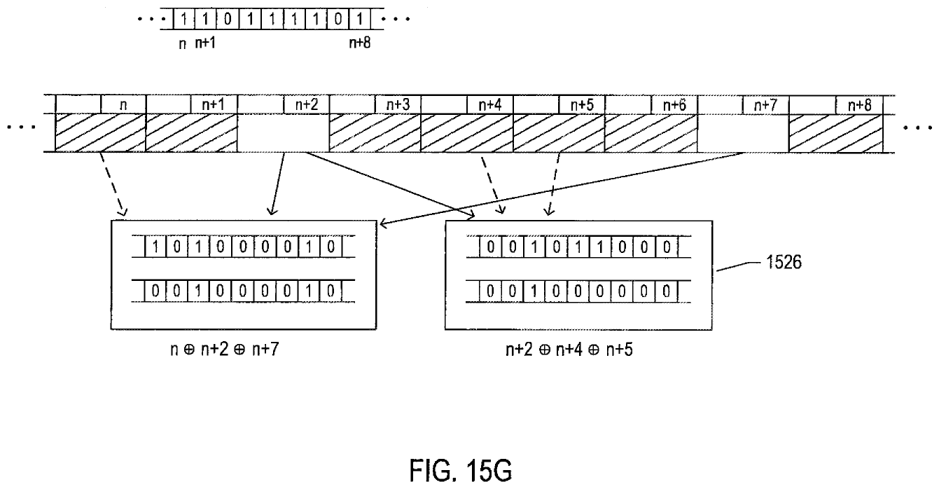

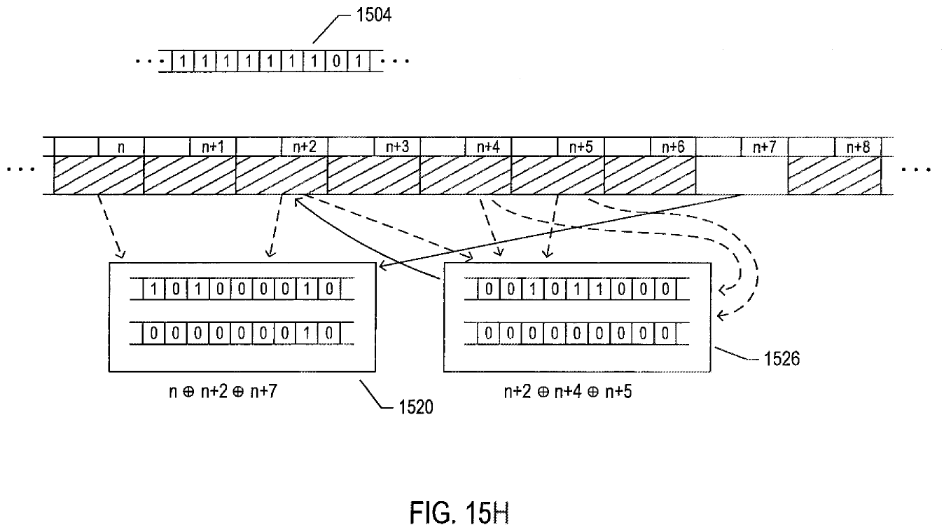

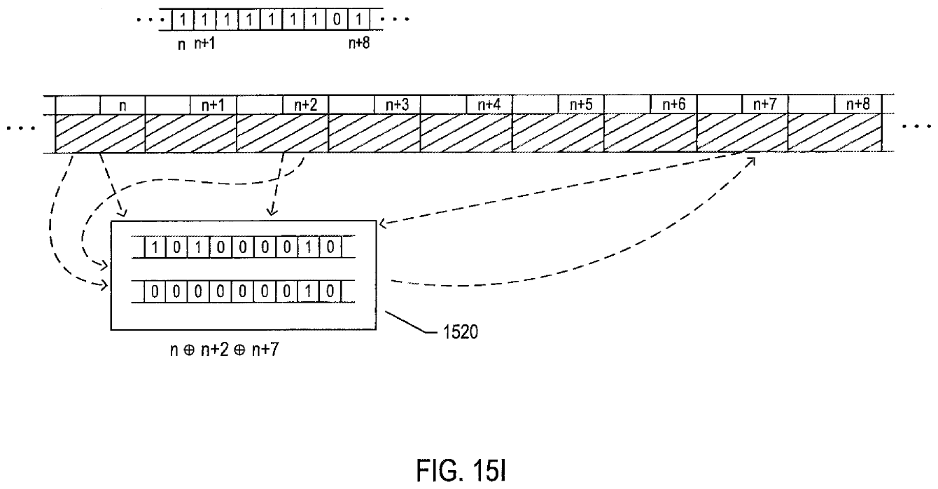

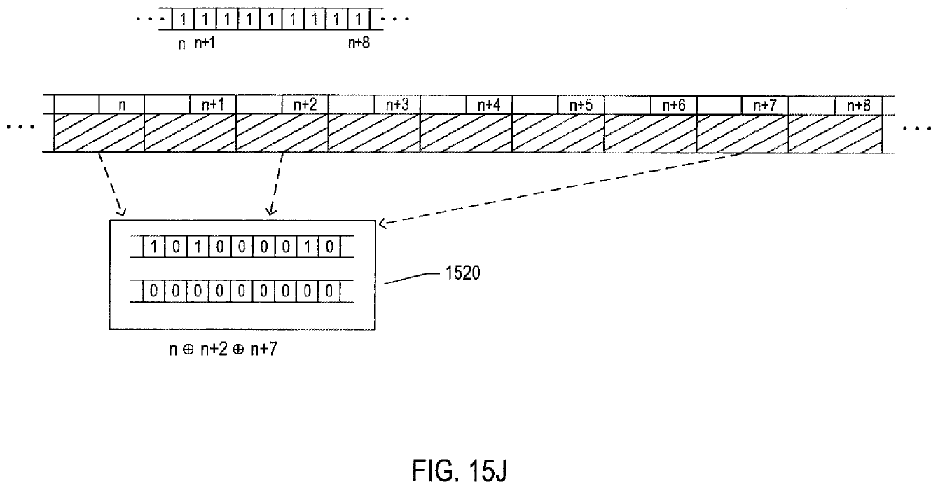

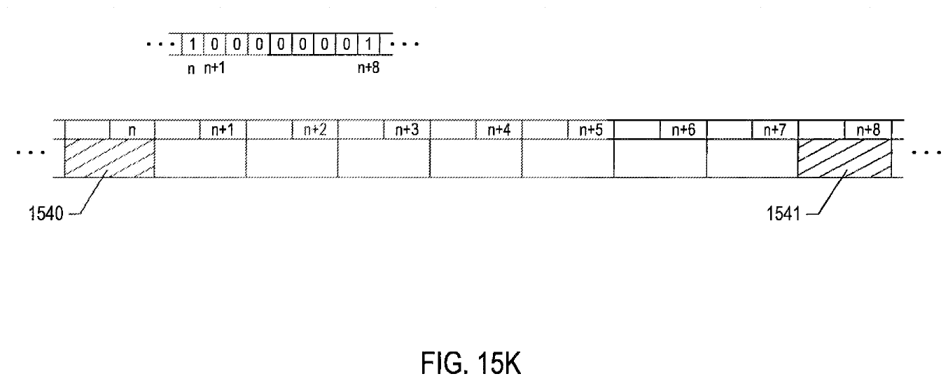

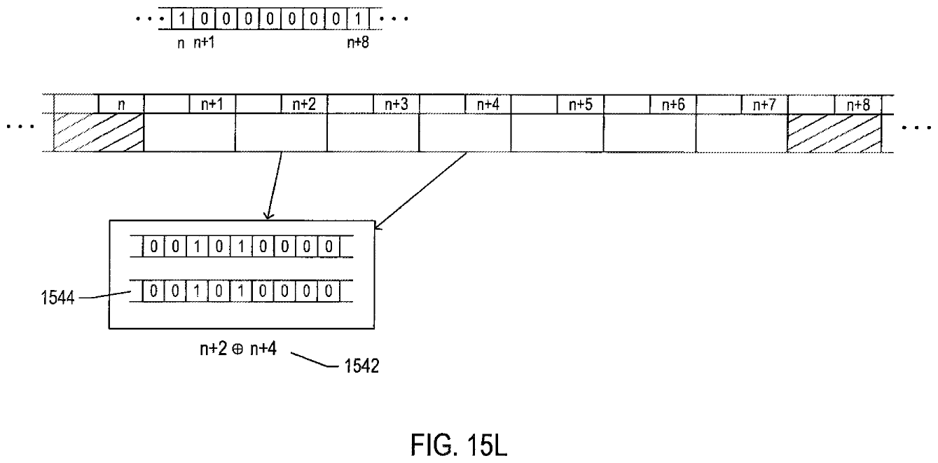

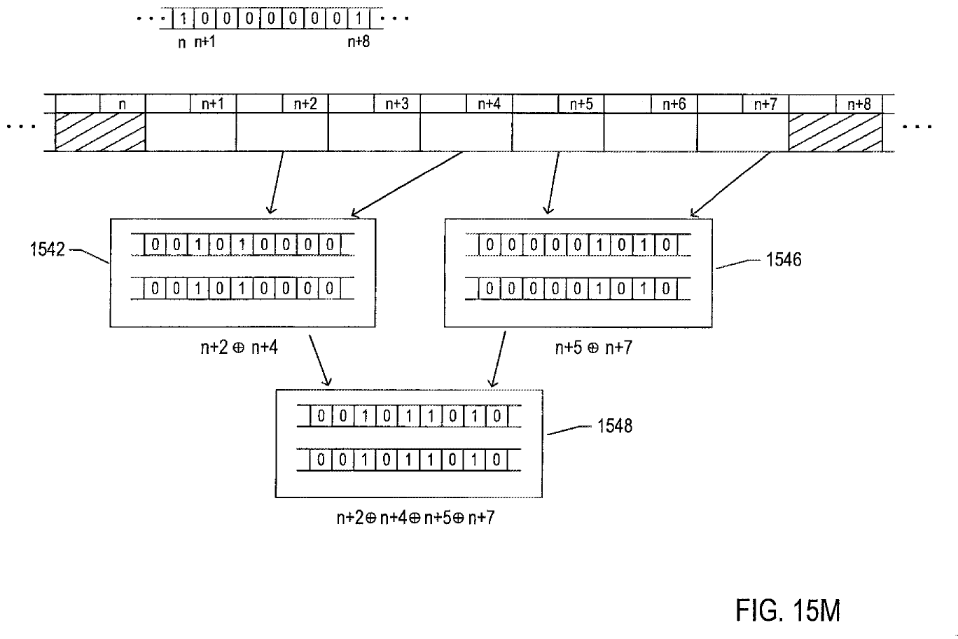

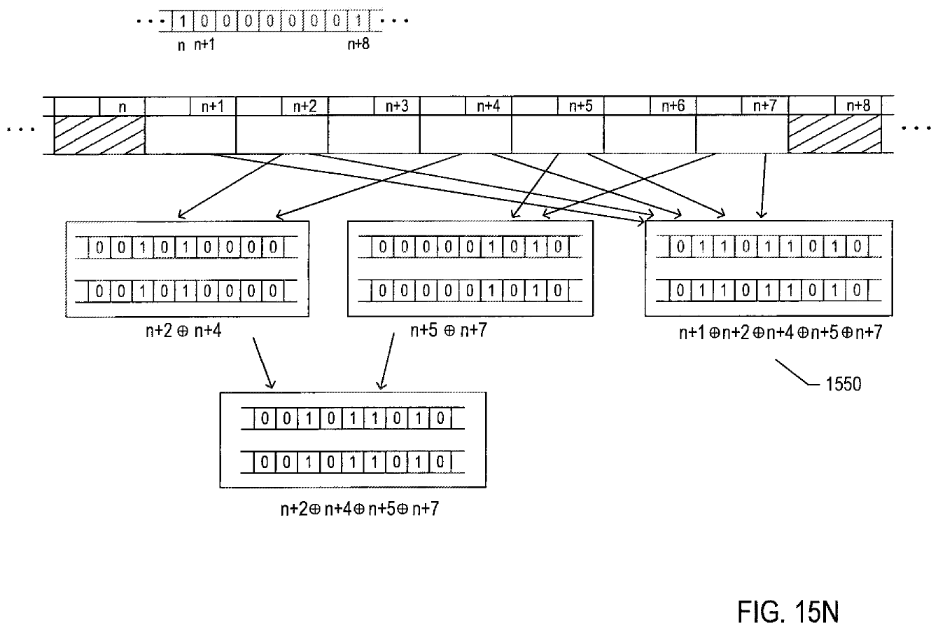

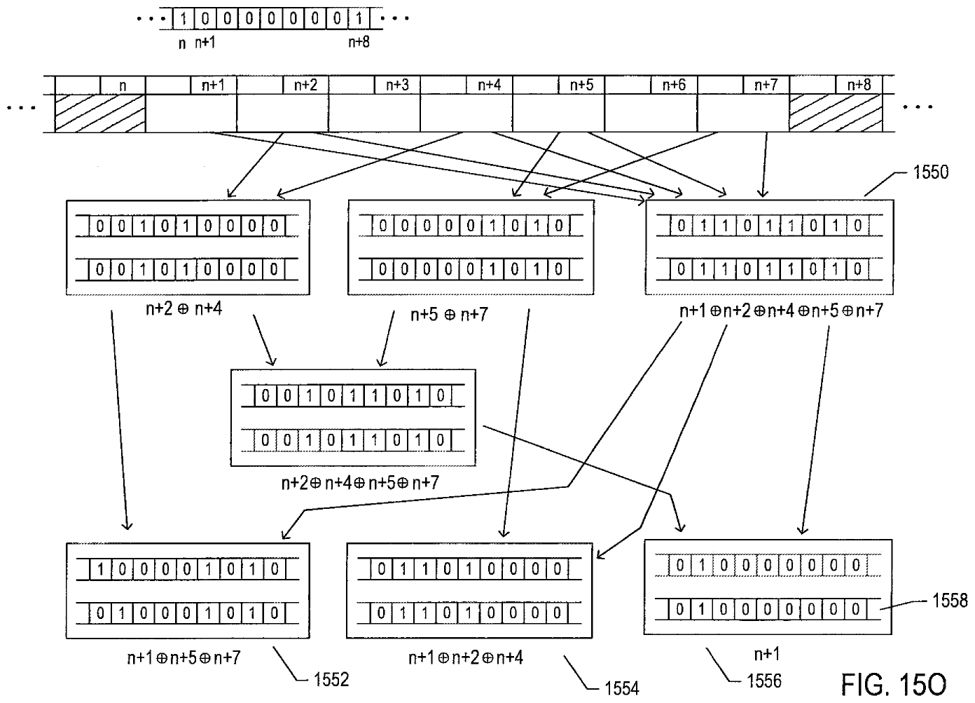

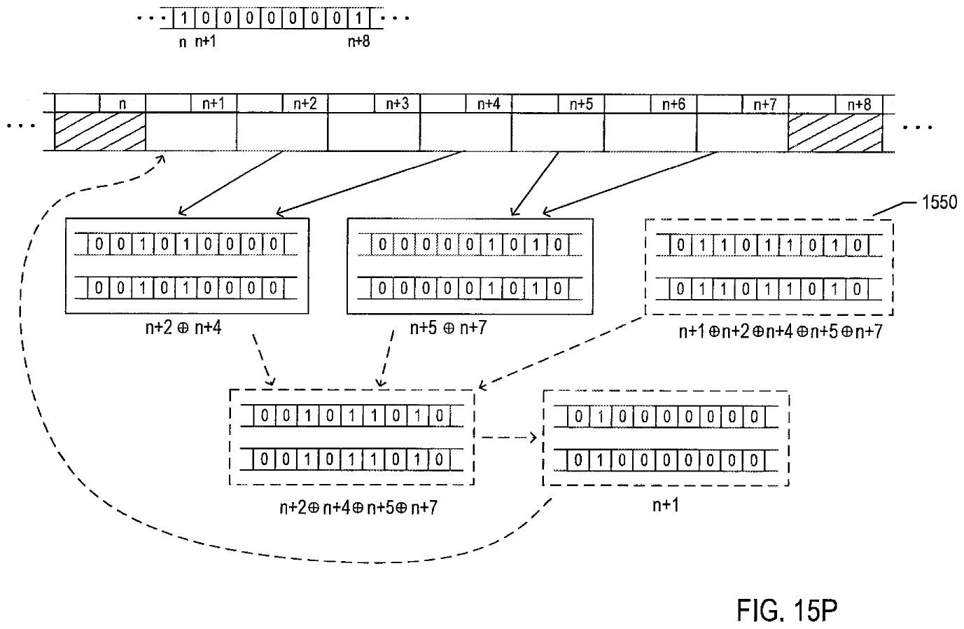

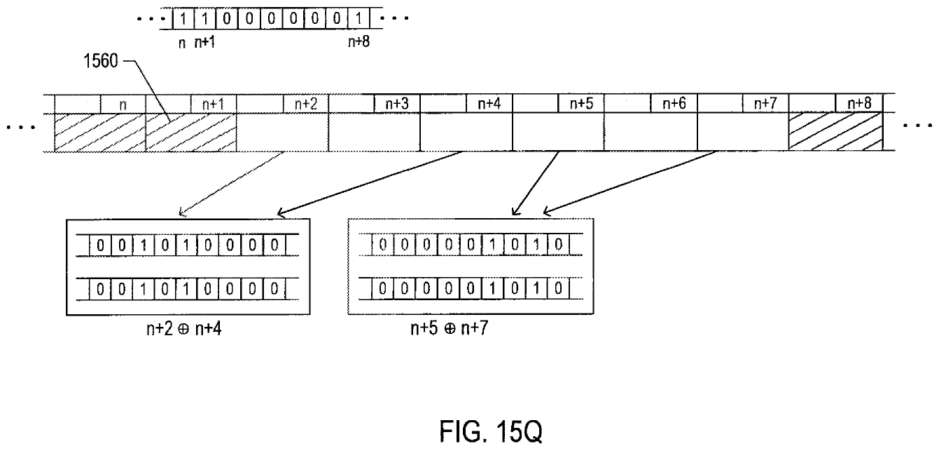

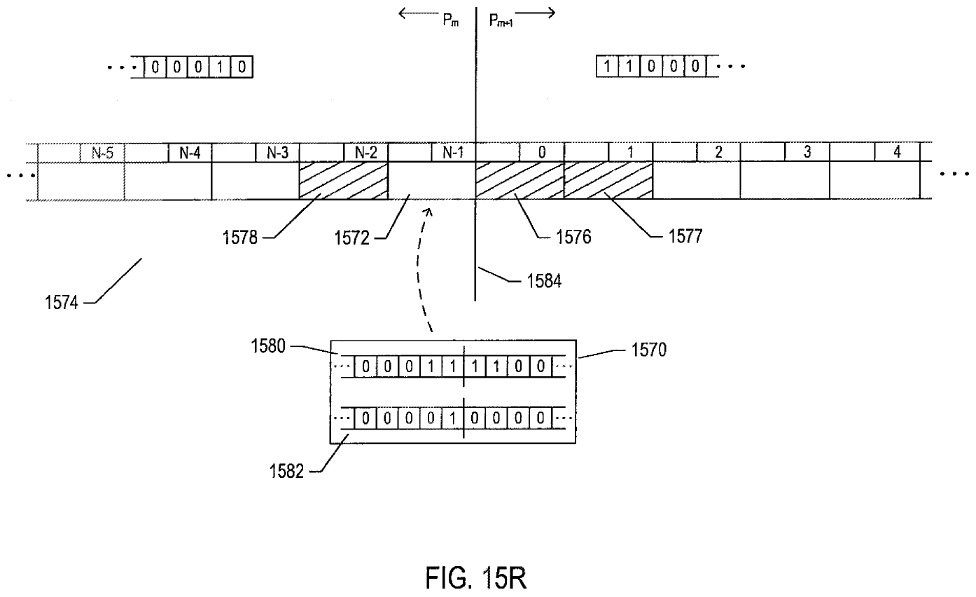

FIGS. 15A-R illustrate operation of the currently disclosed communications protocol with respect to one partition of the data structure discussed with reference to FIGS. 14A-B. A small 9-packet portion of a partition of the data structure 1502 is shown in each of FIGS. 15A-Q. The rcvMask 1504 for the portion of the partition is also shown. The crosshatched packet data structures, such as packet data structure 1506, represent packets that have been successfully transmitted to the receiver. The pattern of crosshatching within the portion of the partition is mirrored by the pattern of “1 ” bits in the revMask. The sequence-number fields of the packet data structures, such as sequence-number field 1508 of packet data structure 1506, are also shown. Thus, at the point in time represented by FIG. 15A, the illustrated portion of the partition includes six successfully transmitted and received packets, represented by packet data structures 1506 and 1510-1514, and three unreceived packets 1516-1518.

As shown in FIG. 15B, the receiver receives a new check packet, represented by graph node 1520, from the sender. The check packet was generated by the multiple-XOR operation indicated by expression 1521. Thus, it was generated by a multiple-XOR operation that included packets n, n+2, and n+7 as operands. The mask 1522 indicates, with “1” bits, the packet data structures corresponding to packets n, n+2, and n+7 that reference the graph node 1520, which are, of course, the packets used as operands in the multiple-XOR operation that generated the check packet represented by the graph node 1520, and the reduced mask 1523 within the graph node 1520 indicates the XOR or multiple-XOR combination of unreceived packets that can be revealed when sufficient additional information is obtained from subsequently received additional check packets. Because there are two “1” bits in the reduced mask 1523, the check packet represented by the graph node is not immediately useful for generating an unreceived packet. However, when sufficient additional information is received to decrease the number of “1” bits in the reduced mask 1523 to one, the check packet represented by the graph node can be used to generate the packet corresponding to the single “1” bit in the reduced mask. Since the received check packet cannot be immediately used, it is represented by the graph node and added to the check-packet graph corresponding to the partition. In FIG. 15B, and in subsequent FIGS. 15C-15J, dashed straight arrows, such as dashed straight arrow 1524, represent already-received data packets included in the XOR or multiple-XOR operation that generates the check packet represented by a first-level graph node and solid arrows, such as dashed straight arrow 1525, represent data packets that have not been received or revealed that are included in the XOR or multiple-XOR operation that generates the check packet represented by a first-level graph node. Only solid arrows correspond to references included in packet data structures to graph nodes. In fact, the ability to avoid references in packet data structures corresponding to received or revealed data packets represents a significant savings in memory and computational bandwidth. In essence, the graph data structures corresponding to partitions, in combination with the packet data structures of the partitions, can be considered to be larger graphs in which the packet data structures represent the lowest-level nodes. The lowest-level nodes and the graph nodes representing check packets, the first level nodes of the graph data structures, can be considered to be two sets of nodes of a bipartite graph. That bipartite graph is generally sparse since packet data structures corresponding to received or revealed data packets do not reference graph nodes corresponding to check packets. Thus, by “sparse graph,” the current application means that the bipartite graph corresponding to the lowest-level and first-level nodes in a larger graph in which the packet data structures represent the lowest-level nodes is sparse.

As shown in FIG. 15C, an additional check packet is received and represented by graph node 1526. The additional check packet is also not immediately useful since there are three “I” bits in the reduced mask 1527 for graph node 1526. Thus, is represented by graph node 1526, which has been added to the graph for the partition portion illustrated in FIGS. 15A-J. However, as shown in FIG. 15D, the two graph nodes 1520 and 1526 can be combined, by an XOR operation, to produce a higher-level graph node 1528. Expression 1529 represents the result of the XOR operation that combines graph nodes 1520 and 1526, which can be reduced to expression 1530 by eliminating pairs of identical operands in the expression. Repeated operands cancel one another out. Thus, the higher-level graph node 1528 represents a derived check packet based on previously received check packets. In this case, the reduced mask 1531 for the new graph node 1528 includes only a single “1” bit corresponding to packet n+5. For this reason, the check packet represented by graph node 1528 can be used, along with already received packet n, to produce, or reveal, packet n+5 by the XOR operation check ⊕n=n+5. It should be noted that, as discussed further below, in cases like that shown in FIG. 15D, graph node 1528 need not be created and added to the graph since it is immediately usable and, once used, will contain no further useful information. Furthermore, it is unnecessary to immediately generate the payload for a derived check packet corresponding to a higher-level graph node. Generation of the derived-check-packet payload can be deferred until the derived check packet can actually be used for revealing an additional packet. In essence, a derived check packet represented by a higher-level graph node that provides new, useful information for packet generation is a reduced check packet that represents a derived check message that can be obtained as a combination of fewer multi-packet-message packets than used to generate the check packets represented by the lower-level graph nodes that reference the higher-level graph node.

FIG. 15E illustrates how graph node 1528 is used to reveal packet n+5. Already received packet n is used as an operand in an XOR operation that uses the derived check packet corresponding to graph node 1528 to produce packet n+5. The packet data structure 1517 for packet n+5 is then updated. As shown in FIG. 15F, the revMask 1504 for the partition is also updated, as are the reduced masks for graph nodes 1520, 1526, and 1528. As shown in FIG. 15G, since the reduced mask for graph node 1528 contains no “1” bits following generation of packet n+5 and updating of the revMask 1504 and the reduced masks for graph nodes 1520, 1526, and 1528, graph node 1528 is removed from the graph since it no longer contains useful information. Moreover, graph node 1526 now contains only a single “1” bit and can therefore be immediately used to produce the packet corresponding to that “1 ” bit, packet n+2. Packet n+2 is generated using the check-packet payload referenced by graph node 1526 via the multiple-XOR operation check⊕n+4⊕n+5=n+2. FIG. 15H shows generation of packet n+2 and update of the revMask 1504 and the reduced masks for graph nodes 1520 and 1526. Because the reduced mask for graph node 1526 now contains no “1” bits, graph node 1526 can be removed, as shown in FIG. 15I. As also shown in FIG. 15I, the reduced mask for graph node 1520 now contains only a single “1” bit and can therefore be immediately used to produce the packet corresponding to that “1” bit, packet n+7. Packet n+7 is generated using the check-packet payload referenced by graph node 1520 via the multiple-XOR operation check⊕n⊕n+2=n+7. Following update of the revMask 1504 and the reduced mask for graph node 1520, as shown in FIG. 15J, the reduced mask for graph node 1520 now contains no “1” bits and can be removed. Furthermore, the packets in the illustrated portion of the partition are now all received or revealed, as indicated by crosshatching and by the presence of only “1” bits in the revMask 1504. At this point, it may be possible to scroll the data structure can be scrolled forward, as discussed above with reference to FIG. 14B.

FIG. 15K illustrates a portion of a partition that includes two already received or revealed data packets represented by packet data structures 1540-1541. As shown in FIG. 15L, a new check packet 1542 is received. Since the reduced mask 1544 in this new check packet contains more than a single set bit, it is not immediately useful and is thus added as a first-level node to the graph associated with the partition. As shown in FIG. 15M, a second new check packet 1546 is received and, like check packet 1542, is not immediately useful and is thus added to the graph for the partition has another first-level node. In addition, a derived check packet 1548 is additionally added to the graph as a result of cascading the two first-level nodes. As shown in FIG. 15N, another new check packet 1550 is received and, not being immediately useful, is added as another first-level node to the graph for the partition. As shown in FIG. 15O, additional cascade operations generate two new second-level derived check packets 1552 and 1554 as well as a third-level derived check packet 1556. This third-level derived check packet has only a single bit set in the reduced mask 1558, and thus can be used to reveal data packet n+1. Although check packet 1550 was not immediately useful, it turns out to enable data packet n+1 to be revealed, but this is evident only after adding check packet 1550 is a first-level graph node and then carrying out the multiple cascade operations to eventually generate derived check packet 1556.

FIG. 15P illustrates a useful optimization to avoid adding a newly arrived check packet, such as check packet 1550 in FIGS. 15N-O, that contains sufficient information to reveal a new data packet as a first-level graph node followed by multiple cascade operations in order to determine that the newly arrived check packet can be immediately used to reveal a new data packet. In this case, newly arrived check packet 1550 is not immediately added as a first-level graph node. Instead, the existing first-level nodes are traversed, accumulating indications of first-level check packets that can be included in an XOR product in the case that the XOR product can be used to reveal a new data packet. When the XOR combination of the newly arrived check packet with the first first-level node or with an accumulated XOR product generated from two or more first-level nodes results in a temporary graph node having only a single bit set in the reduced mask, the payload for the temporary graph node can be generated by an XOR operation or multiple-XOR operation and the temporary graph node can then be immediately used to reveal a new data packet (n+1 in the current example). Once the new data packet is revealed, the newly arrived check packet can be discarded, a recursive walk from the packet data structure corresponding to the newly revealed data packet can then be undertaken to update the graph corresponding to the partition. This optimization can therefore short-circuit a great deal of unnecessary complexity in the graph and the computational and memory overheads associated with adding multiple graph nodes only to immediately remove them once cascading results in a derived check packet with a single set bit. Thus, as shown in FIG. 15Q, data packet n+1 is no revealed 1560 and the newly arrived check packet 1550 has been discarded, without having first been added as a first-level graph node along with the additional derived check packets shown in FIG. 15O this optimization is referred to as a horizontal walk because it represents a full or partial traversal of the first-level graph nodes.

FIG. 15R another optimization. During transmission of data packets from a sender to a receiver, it may be the case that several partitions become nearly completely transmitted, but additional check packets are needed to reveal a few final data packets at the receiver side. In such cases, it may be advantageous to transmit check packets that span a partition boundary. A partition-spanning check packet 1570 can be used, in the example shown in FIG. 15R, to reveal data packet N−1 1572 l in partition Pₘ 574 using already-received data packets 1576-1577 in partition Pₘ₊₁ and already-received data packet 1578 in partition Pₘ. Note that the mask 1580 and reduced mask 1582 in the partition-spanning check packet 1570 includes indications for data packets of both partitions Pₘ and Pₘ₊₁ near the partition boundary 1584. The use of partition-spanning check packets can often reduce the number of check packets needed to be sent by the sender in order to complete transmission of pairs of not yet completely transmitted partitions. As with the non-partition-spanning check packets, they can be used to immediately reveal a new data packet when only a single bit is set in their reduced masks. Partition-spanning check packets that cannot be reduced, via XOR operations using received or revealed data packets, to include only bits in the reduced mask corresponding to data packets of a single partition are discarded. Nodes representing partition-spanning check packets with multiple set reduced-mask bits corresponding to data packets in only a single partition can be added to the graph for that partition for subsequent use, just as a node representing a non-partition-spanning check packet with multiple set reduced-mask bits can be added to the graph for the partition associated with the non-partition-spanning check packet.

Because of the tree-like nature of the check-packet graph, it is immediately apparent that use of check packets for generating unreceived packets is inherently recursive, in nature. In the following control-flow diagrams, an implementation of the currently disclosed FEC-based communications protocol is provided. The implementation includes recursive routines.

It is the check-packet graphs associated with the partitions in the currently disclosed data structure that provide, along with the currently disclosed communications protocol, for significantly increased efficiency over currently available XOR-based FEC-based communications protocols. In currently available XOR-based FEC-based communications protocols, check packets are not systematically stored and organized in order to allow for generation of derived check packets and use of the derived check packets for generating additional unreceived packets. Even though a received check packet may not be immediately useful, once one or more additional check packets are received, a check packet or derived check packet can result in a chain of unreceived-packet generation. By systematically storing and organizing received check packets, the currently disclosed communications protocol can forestall the transmission of many redundant and useless check packets. The check-packet graph can include multiple levels of derived check packets above an initial level of check packets. The currently disclosed data structure is the advantageous property of being linearly scalable. The number of partitions that can be concurrently transmitted by the sender can be increased to increase network-bandwidth utilization in order to optimize message transmission in high-latency networks. Should the memory overheads become an issue, the nodes from the graphs associated with partitions can be removed and deallocated randomly or systematically along with data buffers referenced from them to free up memory without increasing transmission failure rates. Moreover, the check-packet-based operations used to recover from failed data-packet transmissions can be concurrently carried out over multiple partitions, which may significantly decrease the overall latency of message transmission.

The currently disclosed communications protocol is FEC-based because check packets are automatically sent by the sender and represent redundant information that can be used by the receiver to generate unreceived packets. However, the disclosed communication protocol is also somewhat ARQ-like, because the redundant information is not initially sent, but is instead only sent in the case that packet transmission fails, and is automatically sent without the need to wait for ACK messages. In the remaining portion of this document, an example implementation of the currently disclosed communications protocol is provided using control-flow diagrams. This implementation is meant to illustrate the generation and use of check packets, derived check packets, and check-packet graphs.

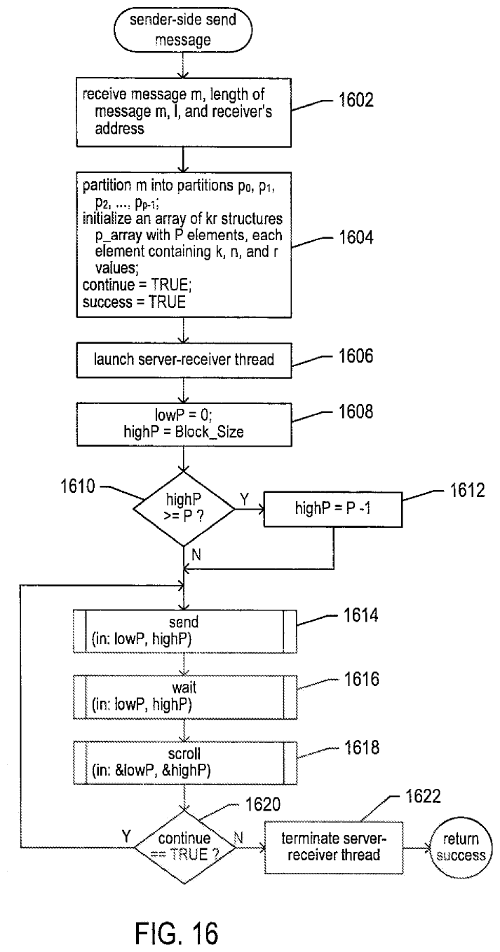

FIG. 16 provides a control-flow diagram for a sender-side routine that sends a message to a receiver using the currently disclosed communications protocol. In step 1602, the sender-message routine receives a message m, an indication of the length 1 of message m, and the receiver's address. The message may be received as a reference to a stored message or in other ways. Details at that level are not relevant to illustrating operation of the currently disclosed communications protocol, and are not therefore discussed at length. In step 1604, the sender-message routine partitions message m into multiple partitions, each partition corresponding to multiple packets. An array is initialized to contain k, h, and r values for each partition, where k is the number of packets in the partition, h is the highest-numbered packets in the partition that has been indicated to have been received by the receiver, and r is the number of successfully transmitted packets in the partition. Initially, the k values are known following the message partitioning and h values are set to −1, and the r values are all set to 0. Two global Boolean variables continue and success are set to TRUE. The value stored in variable success is returned by the routine to indicate success or failure and the variable continue indicates whether or not the send-message routine should continue sending check packets to the receiver. In step 1606, the send-message routine launches a server-receiver thread, discussed below. In step 1608, two local variables lowP and highP are set to 0 and to a constant Block_Size, respectively. These variables control the window of partitions that are currently being transmitted to the receiver. When the value stored in variable highP is greater than or equal to the number of partitions P, as determined in step 1610, highP is set to P−1, in step 1612, where P−1 is the highest sequence number for the partitions of message n. In step 1614, a routine “sender” is called to transmit packets and check packets within the current window of partitions. In step 1616, the send-message routine calls a routine “wait” to wait for a short period of time that depends on the size of the current window. In step 1618, the send-message routine calls a routine “scroll” to possibly advance the partition window in the case that one or more of the lowest-numbered partitions have been completely successfully transmitted to the receiver. When the variable continue contains the Boolean value FALSE, as determined in step 1620, the send-message routine terminates the server-receiver thread in step 1622 and returns the value stored in variable success. Otherwise, control returns to step 1614 for another iteration of the loop that includes steps 1614, 1616, 1618, and 1620.

In the implementation illustrated in FIG. 16-33, each partition is associated with its own length, k, and its own value r indicating the number of data packets in the partition and have been received by the receiver. In alternative implementations, all of the partitions have fixed-length data packets and only a single value r is maintained for the entire message, which is distributed across partially-transmitted partitions for the purpose of check-message generation and transmission.

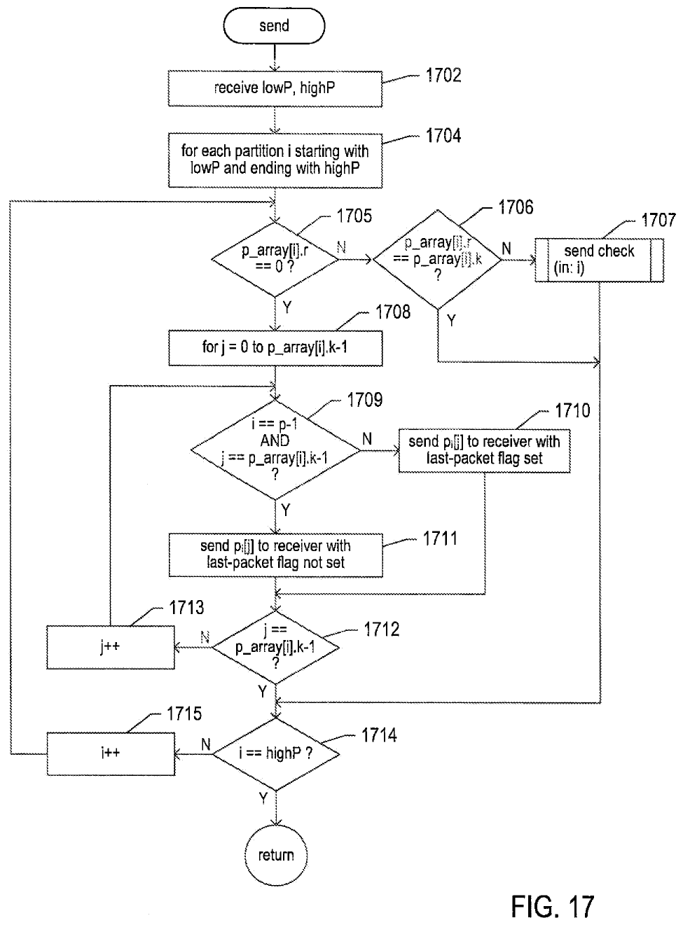

FIG. 17 provides a control-flow diagram for the routine “send,” called in step 1614 of FIG. 16. In step 1702, the arguments lowP and highP arc received. In the outer for-loop of steps 1704-1715, each partition in the range [lowP, highP] is considered. When the number of successfully transferred packets in the partition is not equal to 0, as determined in step 1705, and when the number of successfully transferred packets in the partition is not equal to the total number of packets in the partition, as determined in step 1706, the routine “send” calls a routine “send check.” in step 1707, to send a check packet to the receiver. Otherwise, when the number of successfully transferred packets in the partition is equal to 0, as determined in step 1705, the “sender” routine initiates execution of an inner for-loop of steps 1708-1713. In this inner for-loop, each packet j in the currently considered partition i is considered. When the currently considered packet is the final packet of the message m, as determined in step 1709, the routine “send” sets a last-packet flag in the packet header and sends the packet to the receiver, in step 1710. Otherwise, in step 1711, the routine “send” sends a packet without the last-packet flag set to the receiver. In alternative implementations, a last-packet flag is not needed since the number of packets is computable from the message size.

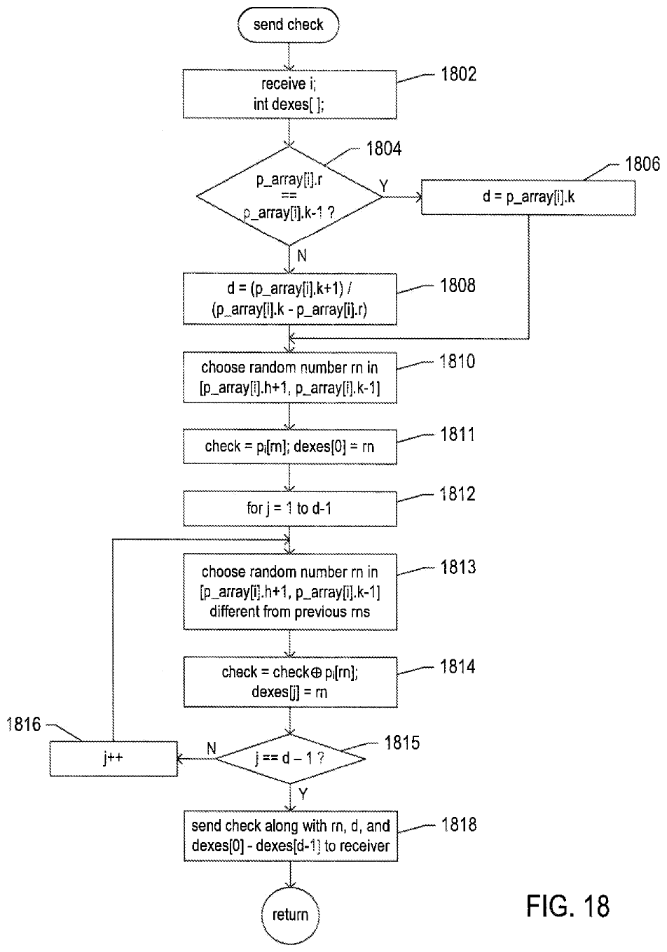

FIG. 18 provides a control-flow diagram for the routine “send check” called in step 1707 of FIG. 17. In step 1802, the routine “send check” receives a partition indication i and initializes a local array dexes. When the number of successfully transferred packets in the partition is one less than the total number of packets in the partition, as determined in step 1804, local variable d is set to the number of packets in the partition, in step 1806. Local variable d is an indication of the dimension of or number of operands to use in, the multiple XOR operation to generate a check packet. Including all of the packets of the partition in the multiple XOR operation ensures that the final packet can be generated by the receiver upon receiving the check packet. Otherwise, variable d is set to the floor of the number of packets in the partition plus 1 divided by the number of packets that have not been successfully transferred, in step 1808. The division operation in step 1808 is integer division rather than real division. In step 1810, the routine “send check” chooses a random number rn within a range of packet sequence numbers for the partition beginning with the number of the first unacknowledged packet. In step 1811, a nascent check packet is initialized as the packet of the currently considered partition i with sequence number rn, and the first element of the array dexes is set to rn. Then, in the for-loop of steps 1812-1816, an additional d−1 packets are randomly selected from the partition and successively used in XOR operations to construct the check packet of dimension d. Of course, all of the d selected packets need to be different from one another. In step 1818, the check packet is sent, along with indications of the packets used to generate the check packet, to the receiver. There are a variety of additional optimizations that can be implemented with respect to check-packet generation and transmission. As discussed below with reference to FIG. 15R, partition-spanning check packets can be generated and sent when the number of unreceived data packets in each of two adjacent partitions is below some threshold number. This can be extended to check packets that spend more than two partitions, in a sense combining multiple partitions into a single aggregate partition. An additional optimization involves occasionally sending higher-dimensional check packets, at certain points in time, then the dimension computed in step 1808. Furthermore, in many implementations, the number indications of the packets used to generate the check packet are not included in check packages because a pseudorandom-number generator in the receiver side is synchronized with the pseudorandom-number generator used to generate check packets on the receiver side, allowing the receiver side to determine, for each received check packet, the packets used to generate the check packet.

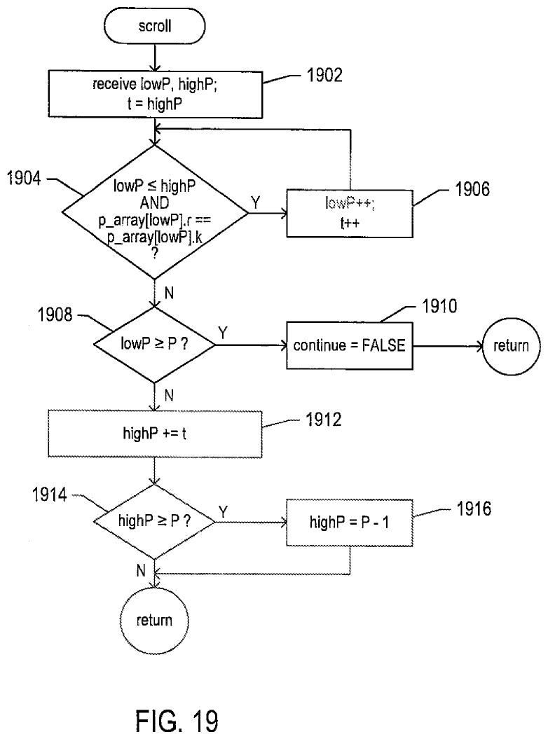

FIG. 19 provides a control-flow diagram for the routine “scroll” called in step 1618 of FIG. 16. In step 1902, the routine “scroll” receives indications of the current partition window, lot-P and highP, and sets local variable t to the value highP. In step 1904, when the partition indicated by lowP has been successfully transmitted to the receiver and when lowP is less than or equal to highP, the routine “scroll” increments both lowP and t, in step 1906, after which control returns to step 1904. When lowP is greater than or equal to the number of partitions in message m, as determined in step 1908, the variable continue is set to FALSE, in step 1910, and the routine “scroll” returns. Otherwise, in step 1912, the routine “scroll” increases highP by i. When highP is now greater than or equal to P, as determined in step 1914, highP is set to P−1, in step 1916, since P−1 is the highest sequence number for a partition for message m.

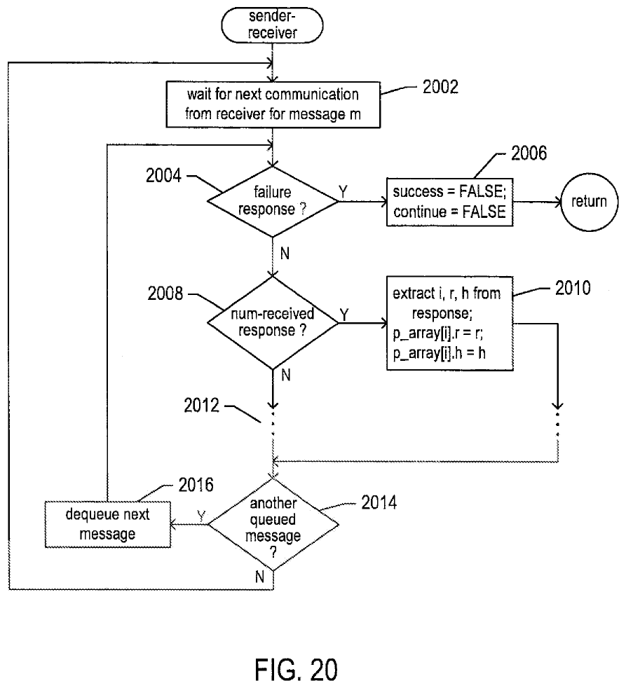

FIG. 20 provides a control-flow diagram for the sender-receiver thread launched in step 1606 of FIG. 16. In step 2002, the sender-receiver routine waits for a next event associated with message m. When the next event is reception of a failure message, as determined in step 2004, the sender-receiver thread sets variables success and continue to FALSE, in step 2006, and returns. By doing so, the sender-receiver routine communicates to the send-message routine that further transmissions to the receiver should be discontinued and that a failure indication should be returned to the caller of the send-message routine. When the next event is reception of a num, received response from the receiver, in step 2008, the sender-receiver thread extracts an indication of the partition i and the number of successfully transmitted packets r from the response and updates the entry in p array for partition i, in step 2010. Ellipsis 2012 indicates that other events may be handled by the sender-receiver thread. When there is another message queued for handling, as determined in step 2014, the message is dequeued, in step 2016, and control returns to step 2004. Otherwise, control returns to step 2002.

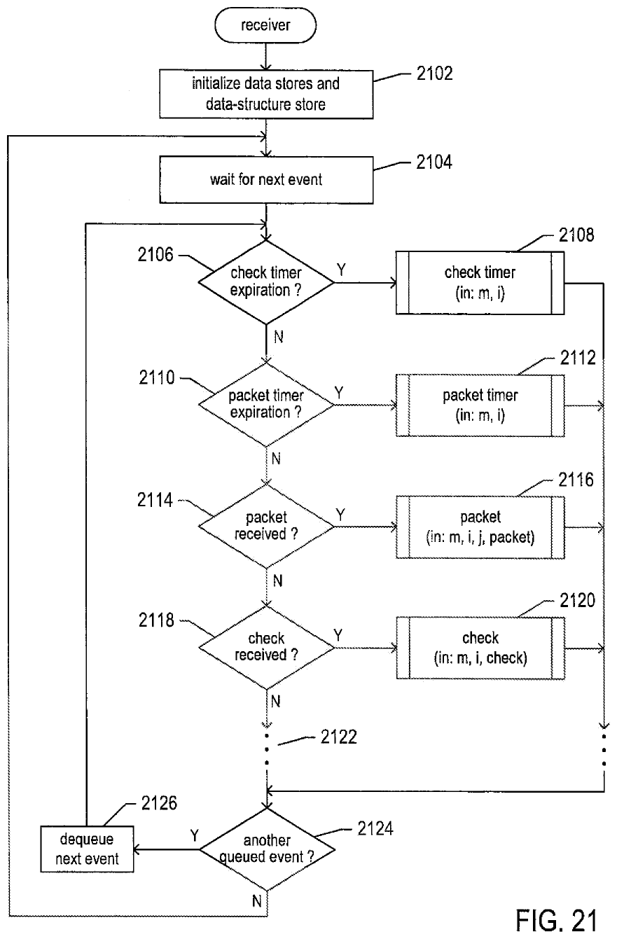

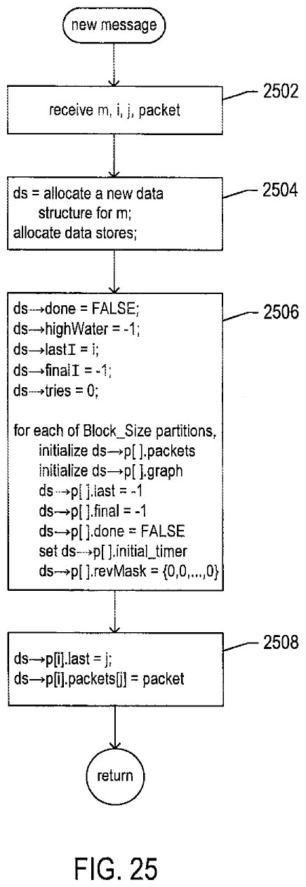

FIG. 21 provides a control-flow diagram for a receiver that receives multi-packet messages according to the currently disclosed communications protocol. In step 2102, the receiver initializes data stores for storing check packets and packet data payloads as well as a data-structure store for maintaining data structures for messages discussed above with reference to FIGS. 14A-B. The various fields of the data structure discussed above with reference to FIGS. 14A-B are discussed, in detail, with reference to FIG. 25, below. In step 2104, the receiver waits for the occurrence of a next event. When the next event is a check timer expiration, as determined in step 2106, a check-timer handler is called, in step 2108. When the next event is a packet timer expiration, as determined in step 2110, a packet-timer handler is called, in step 2112. When the next event is receipt of a packet, as determined in step 2114, a packet handler is called, in step 2116. When the next event is receipt of a check packet, as determined in step 2118, a check-packet handler is called, in step 2120. Ellipsis 2122 indicates that additional types of events may be handled by the receiver. When there is another queued event, as determined in step 2124, the event is dequeued, in step 2126, with control flowing back to step 2106. Otherwise, control flows back to step 2104.

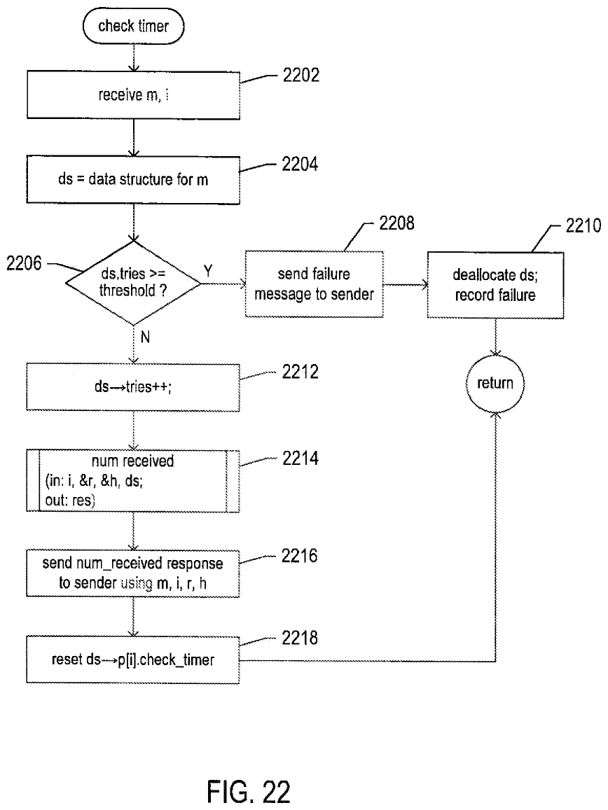

FIG. 22 provides a control-flow diagram for the check-timer handler called in step 2108 of FIG. 21. In step 2202, the check-timer handler receives an indication of a message m and a partition within the message i. In step 2204, reference variable ds is set to reference the data structure for message m. When the field tries of the data structure referenced by ds stores a value that is greater than or equal to a threshold value, as determined in step 2206, the check-timer handler sends a failure message to the sender of the message m, in step 2208, and then, in step 2210, deallocates the data structure referenced by ds and records failure of reception of message m. Otherwise, in step 2212, the check-timer handler increments the field tries of the data structure referenced by ds. The check-timer handler then calls the routine “num_receive,” in step 2214, to determine the number of packets received for partition i and returns that number of packets to the sender in a num_received response, in step 2216. In step 2218, the check-timer handler resets the check timer of the data structure referenced by ds. Alternative implementations may not employ a check timer, but may instead use other protocol-based information to detect failed communications.

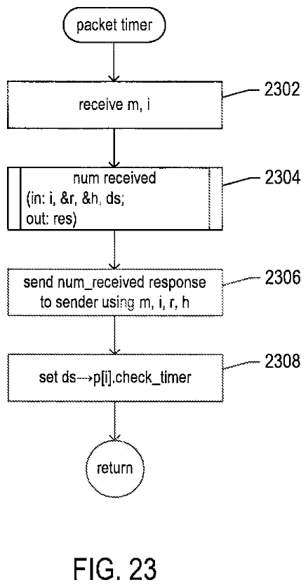

FIG. 23 provides a control-flow diagram for the packet-timer handler called in step 2112 of FIG. 21. In step 2302, the packet-timer handler receives an indication m of a message and an indication of a partition i within the message. The packet-timer handler then calls the routine “num_received,” in step 2304, to determine the number of packets received for partition i and returns that number of packets to the sender in a num_received response, in step 2306. In step 2308, the packet-timer handler sets the check timer in the data structure ds for partition i. Alternative implementations may not employ a packet timer, but may instead use other protocol-based information to detect failed communications.

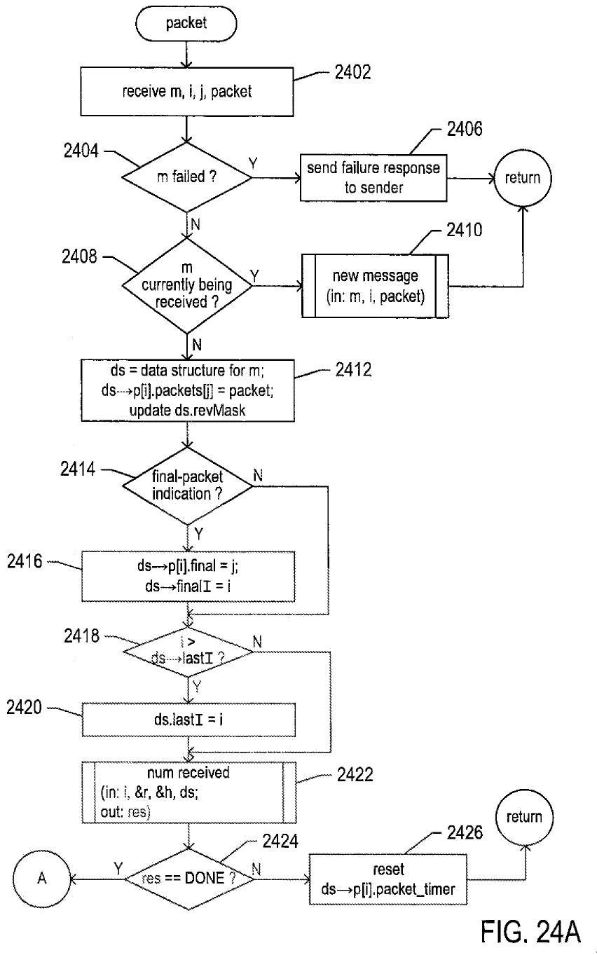

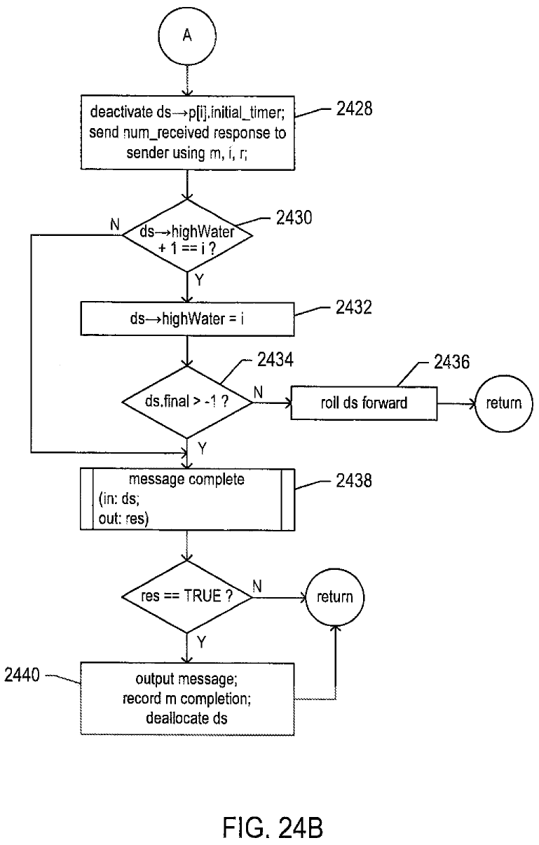

FIGS. 24A-B provide a control-flow diagram for the routine “packet.” called in step 2116 of FIG. 21. In step 2402, the routine “packet” receives an indication m of a message, an indication of a partition i within the message, and a newly received packet with sequence number i within partition i. In step 2404, the routine “packet” determines whether or not reception of message m has been recorded to have failed. When reception of message m has failed, the routine “packet” sends a failure response to the sender, in step 2406, and returns. Otherwise, in step 2408, the routine “packet” determines whether message m is currently being received. When message m is not currently being received, the routine “packet” calls a routine “new message,” in step 2410, to handle the first packet received for message m. Otherwise, in step 2412, the routine “packet” sets reference variable ds to the data structure for message m and initializes the packet data structure j within data structure ds using the newly received packet. When the received packet includes a final-packet indication, as determined in step 2414, the field final for the partition i is set to j and the field finalI for data structure ds is set to i, in step 2416. When i is greater than the partition sequence number stored in the lastI field of the data structure ds, as determined in step 2418, the lastI field of the data structure ds is set to i. In step 2422, the routine “packet” calls the routine “num_received” to determine the number of packets received for partition i. When all of the packets of partition i have not been received, as determined in step 2424, the routine “packet” resets the packet timer of the data structure ds, in step 2426, and returns. Otherwise, control flows to step 2428 in FIG. 24B. In step 2428, the routine “packet” deactivates an initial timer of the data structure ds and sends a num_received response to the sender. When 1 plus the value in the highWater field of data structure ds is equal to i, as determined in step 2430, the highWater field of data structure ds is set to i, in step 2432. When the final partition of message m has not yet been identified, as determined in step 2434, the ds data structure is rolled forward, as discussed above with reference to FIG. 14B, in step 2436 and the routine “packet” returns. Otherwise, the routine “packet” calls a routine “message complete,” in step 2438, to determine whether or not message m has been successfully received. If so, then in step 2440, the received message is output to a message consumer, the successful reception of message m is recorded, and data structure ds is deallocated. Otherwise, the routine “packet” returns.

FIG. 25 provides a control flow diagram for the routine “new message.” called in step 2410 of FIG. 24A. In step 2502, the routine “new message” receives an indication m of a message, an indication or a partition i within the message, and a newly received packet with sequence number j within partition i. In step 2504, the routine “new message” allocates a data structure ds for the new message and additionally allocates data stores for storing packets and check packets. In step 2506, the routine “new message” initializes the data structure ds. The following fields of the data structure are initialized: (1) done, which indicates whether or not the message has been completely successfully transmitted, and is initialized to FALSE: (2) highWater, which indicates the completely received partition with the greatest sequence number, and is initialized to −1; (3) lastI, which indicates the partition with the highest sequence number for which a packet has been received, and is initialized to i; (4) finalI, which indicates the last partition of the message, which is initialized to −1; and (5) tries, which indicates the number of check-timer expirations, and is initialized to 0. Then, for each of Block_Size partitions, ds->p[0], ds->p[1], . . . , ds->p[Block_Size−1], the following partitioned fields are initialized: (1) the array ds->p[ ].packets, in which the packet data structures reside; (2) ds->p[ ].graph, the check-packet graph, initialized to be empty; (3) ds->p[ ].last, which indicates the last packet that has been received for the partition, initialized to −1; (4) ds->p[ ].final, which indicates the final packet in the partition, and is initialized to −1; (5) ds->p[ ].done, which indicates that the partition has been completely received, and is initialized to FALSE: (6) ds->p[ ].initial_timer, an initial timer for the partition that is set during initialization to expire after a period of time adequate for all packets of the partition to be transmitted; and (7) ds->p[ ].rcvMask, the bitmap indicating the successfully received packets of the partition. In step 2508, the routine “new message” sets the field ds->p[i].last for partition i to j, updates the packet data structure ds->p[i].packets[j] to indicate that packet j has been successfully received, and stores the data payload of packet j in the message data store.

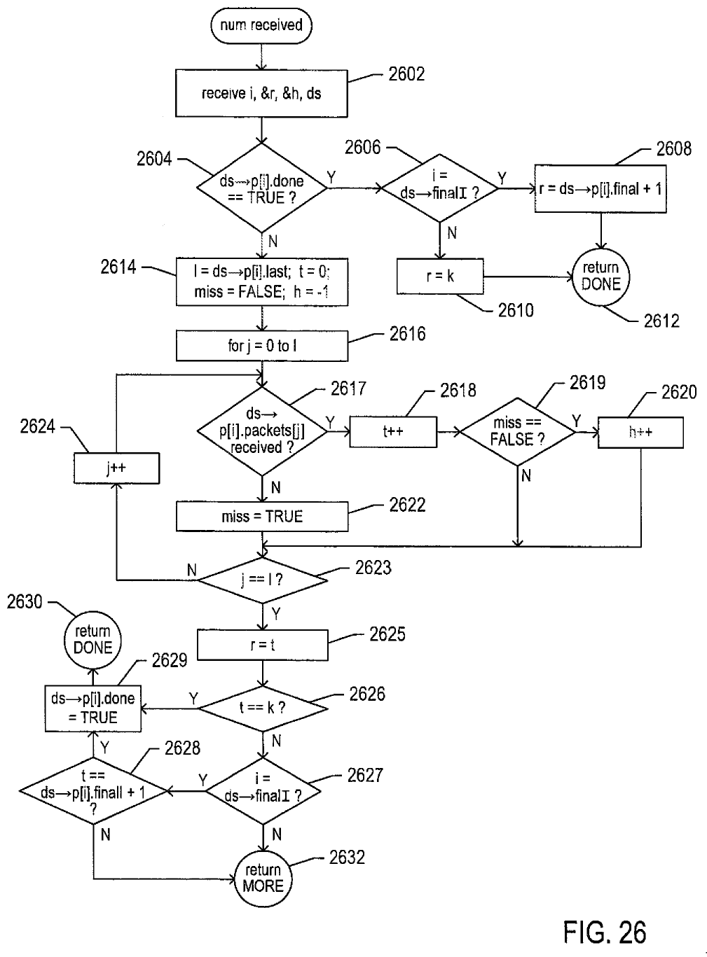

FIG. 26 provides a control-flow diagram for the routine “num received.” called from various other routines, including from the routine “packet timer” in step 2304 and the routine “check timer” in step 2214. In step 2602, the routine “num received” receives an indication of a partition i, a reference to a variable to store a result, r, a reference to a variable to store an indication of the packet number for the highest packet number of an initial set of received data packets, h, and a reference to a data structure ds. In step 2604, the routine “num received” checks to see if the message associated with the data structure ds has been completely received. If so, the routine “num received” determines whether i is the final partition in the message, in step 2606. If so, then the number of messages received is determined in step 2608 while, if not, then the number of messages received is set equal to the number of packets in the current partition, in step 2610. In both cases, the routine “num received” returns the value DONE 2612. When the message has not been fully received, as determined in step 2604, local variable 1 is set to an indication of the highest-numbered packet received for the partition i, local variable t is set to 0, local variable miss is set to FALSE, and h is set to −1, in step 2614. Then, in the for-loop of steps 2616-2624, the routine “num received” counts the number of packets in partition i that have been received and, in step 2625, updates the variable referenced by argument r to store that value. When the number of packets received equals the total number of packets in the partition, as determined in steps 2626 and 2627-2628, the field ds->p[i].done in the data structure for partition i is set to TRUE, in step 2629 and the value DONE is returned 2630. Otherwise, the value MORE is returned 2632.

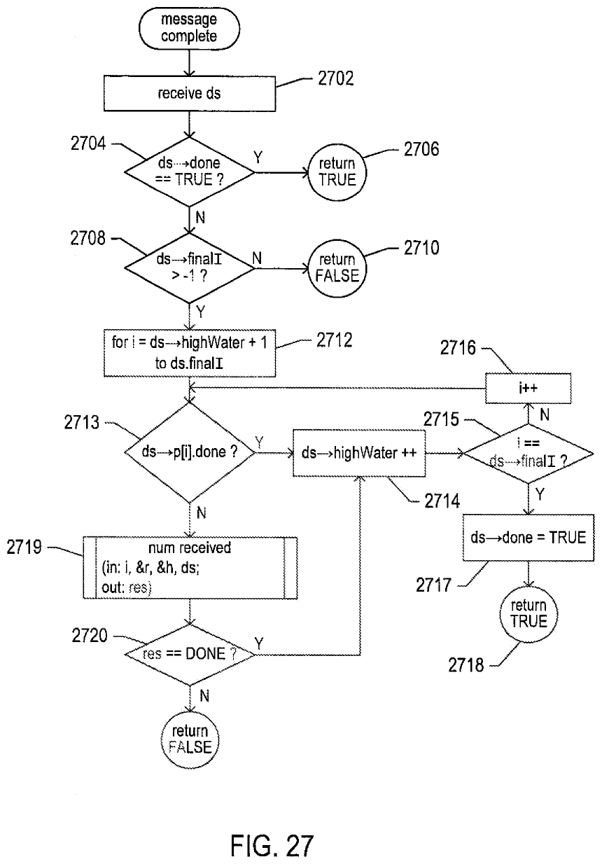

FIG. 27 provides a control-flow diagram for the routine “message complete,” called in various other routines, including in step 2438 of FIG. 24B. The routine “message complete” determines whether or not a message has been completely received by the receiver. In step 2702, the routine “message complete” receives a reference to a data structure ds. When the field ds->done in the data structure has the value TRUE, as determined in step 2704, the routine “message complete” returns the value TRUE 2706. Otherwise, the routine “message complete” determines, in step 2708, whether the final partition has been identified. If not, then the routine “message complete” returns the value FALSE 2710. Otherwise, in the for-loop of steps 2712-2720, the routine “message complete” determines whether the final partition is now completely received, advancing the value of the field highWater, in step 2714, as more complete partitions are determined and setting the field ds->done to the value TRUE, in step 2717, when it is determined that the messages complete.

FIG. 28 provides a control-flow diagram for the routine “check.” called in step 2120 of FIG. 21. It is this routine that uses the check-packet graphs associated with partitions in the data structure for messages to generate unreceived packets from check packets and already received packets. In step 2802, the routine “check” receives an indication of a message m, a partition i within the message, and a check packet check. In step 2804, the data structure for message m is found and a reference to that data structure, ds, is initialized. In addition, a mask and a reduced mask for a potential graph node corresponding to check are prepared, using the identities of the packets used to generate check by the sender as well as the indications of packets already received, in ds->p[i].rcvMask, the revMask for partition i. In step 2806, the routine “check” compares the generated mask and reduced mask to those in current graph nodes for the partition in order to determine whether or not check represents new information in addition to the information represented by the current graph nodes corresponding to previously received check packets, as discussed above with reference to FIGS. 15A-J. When check does not represent new information, as determined in step 2808, a routine “finished” is called, in step 2810 and the routine “check” terminates 2812. In other words, when check does not represent new information, no graph node is prepared for check and no attempt is made to use check to reveal unreceived packets. Otherwise, when the reduced mask prepared for check has only a single bit set, as determined in step 2814, a temporary graph node is prepared for check, in step 2816, referenced by nodePtr in step 2818, where j is set to the packet number corresponding to the single bit set in the reduced mask, and a routine “add new packet” is called, in step 2820, to immediately use check to reveal at least one unreceived packet, after which control flows to step 2810 for termination of the routine “check.” When the reduced mask prepared for check has more than a single bit set, as determined in step 2814, a routine “h walk” is called, in step 2822, to carry out a horizontal walk of the first-level graph nodes, as discussed above with reference to FIGS. 15P-Q. When the routine “h walk” returns the value FALSE, the horizontal walk resulted in a data-packet reveal, and therefore the check message needs no further processing. Otherwise, a routine “cascade” is called, in step 2823, to attempt to use check along with a pair of current graph nodes to generate new information and potentially reveal one or more unreceived packets.

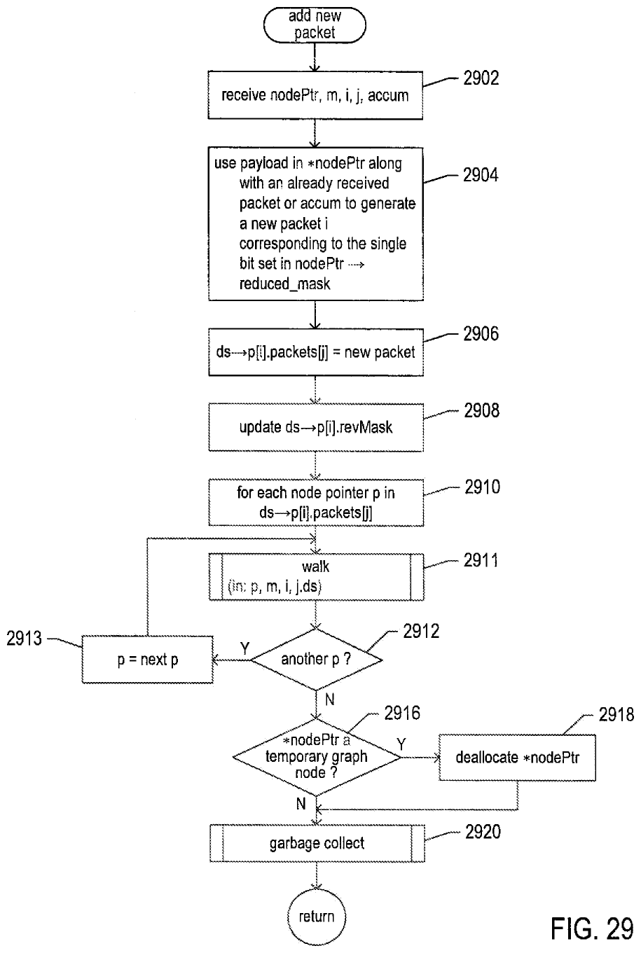

FIG. 29 provides a control-flow diagram for the routine “add new packet,” called in several other routines, including in step 2020 of FIG. 28. In step 3902, the routine “add new packet” receives a pointer to a temporary graph node, nodePtr, an indication of a message m, an indication of a partition i, an indication of a packet within a partition, j, and an optional reference accum to an XOR-accumulated derived temporary node generated by the routine “h walk,” discussed below. In step 2904, the routine “add new packet” uses the payload of the check packet along with one or more already received data packets or, when specified, an XOR-accumulated derived temporary node accum, to generate the unreceived packet j. In step 2906, the routine “add new packet” uses the revealed packet j to update the packet data structure j and adds packet j to the data store. In step 2908, the routine “add new packet” updates the rcvMask for partition i. Then, in the for-loop of steps 2910-2913, the routine “add new packet” calls a routine “walk” to process each pointer in the packet data structure j to a graph node in the graph for partition i. This allows for recursively reviewing additional unreceived packets in view of the newly revealed packet j. When nodePtr references a temporary graph node, as determined in step 2916, the temporary graph node is deallocated, in step 2918. Finally, in step 2920, a garbage-collection routine is called to remove and check packets or derived check packets that no longer contain useful information. In alternative implementations, the garbage-collection routine can be called asynchronously, at periodic intervals, while in still other implementations, the garbage-collection routine is called both during a roll-forward operation of the data structure and when the memory overhead is greater than a threshold value.

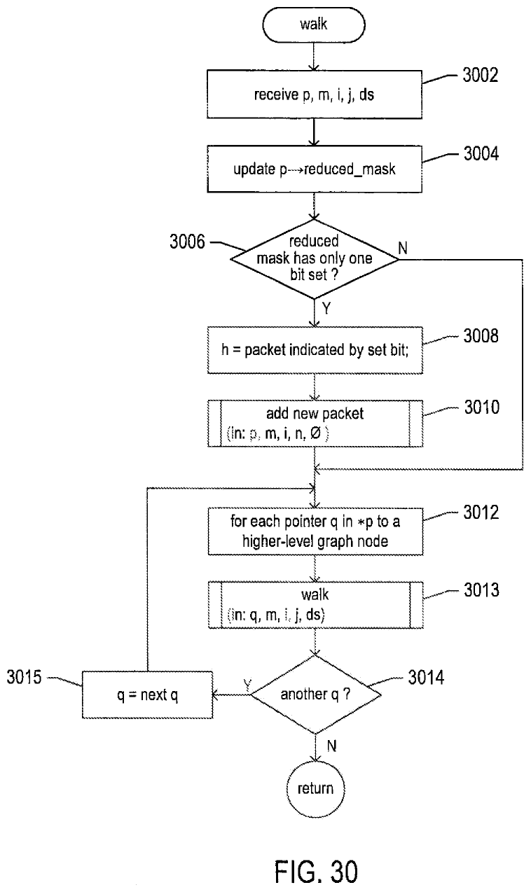

FIG. 30 provides a control-flow diagram for the routine “walk,” called in step 2911 of FIG. 29. The routine “walk” considers each reference, in a graph node, to a higher-level graph node in order to attempt to recursively use the newly revealed packet corresponding to the packet data structure j, previously sent check packets, and already received packets to reveal additional packets. In step 3002, the routine “walk” receives a pointer to a graph node p, an indication of a message m, an indication of a partition i, an indication of a packet within the partition j, and a reference to a data structure ds. In step 3004, the routine “walk” updates the reduced mask for the graph node referenced by argument p. In step 3006, the routine “walk” determines whether or not the reduced mask in the graph node referenced by the argument p now has only a single bit set. If so, then n is set to the sequence number for the packet corresponding to the single set bit, in step 3008 and, in step 3018, the routine “add new packet” is called to use the graph node referenced by argument p along with previously received and revealed packets to reveal a new packet. In the for-loop of steps 3012-3015, the routine “walk” recursively calls itself for each graph-node pointer in the graph node referenced by pointer p.

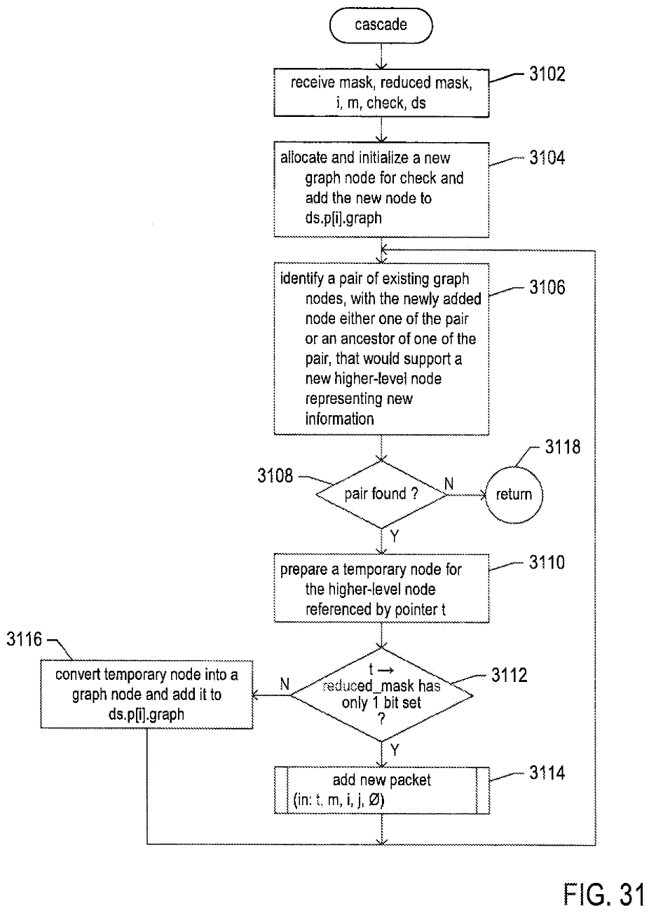

FIG. 31 provides a control-flow diagram for the routine “cascade.” called in step 2824 of FIG. 28. The routine “cascade” adds a graph node representing a check packet to the graph for a partition and then attempts to use the check packet to generate additional derived check packets and attempt to reveal additional unreceived packets. In step 3102, the routine “cascade” receives a mask and reduced mask prepared for a received check packet, an indication of a partition i, an indication of a message m, and the received check packet check. In step 3104, the routine “cascade” allocates and initializes a new graph node to represent check and adds the new graph node to the graph for the partition i. This, of course, involves adding references to the new graph node in the packet data structures corresponding to packets used to generate the check packet corresponding to the new graph node. In step 3106, the routine “cascade” attempts to identify a pair of existing graph nodes that, together with check, would support a new node for the graph that would represent no additional information, as discussed above with reference to FIGS. 15A-J. If such a pair is found, as determined in step 3108, a temporary node for the higher-level node, referenced by the pointer t, is prepared, in step 3110. When the reduced mask for the temporary node has only a single bit set, as determined in step 3112, the routine “add new packet” is called in step 3114 to use the temporary higher-level node to reveal a new packet. Otherwise, the temporary node is converted into a graph node and added to the graph for partition i, in step 3116. Here again, references to the new graph node are added to the pair of graph nodes from which it is derived. In both cases, control returns to step 3106 where the routine “cascade” attempts to find an additional pair of existing graph nodes to support another higher-level node. The loop of generating derived check packets continues until an no additional pair of existing graph nodes is found, as determined in step 3108, in which case the routine “cascade” returns 3118.

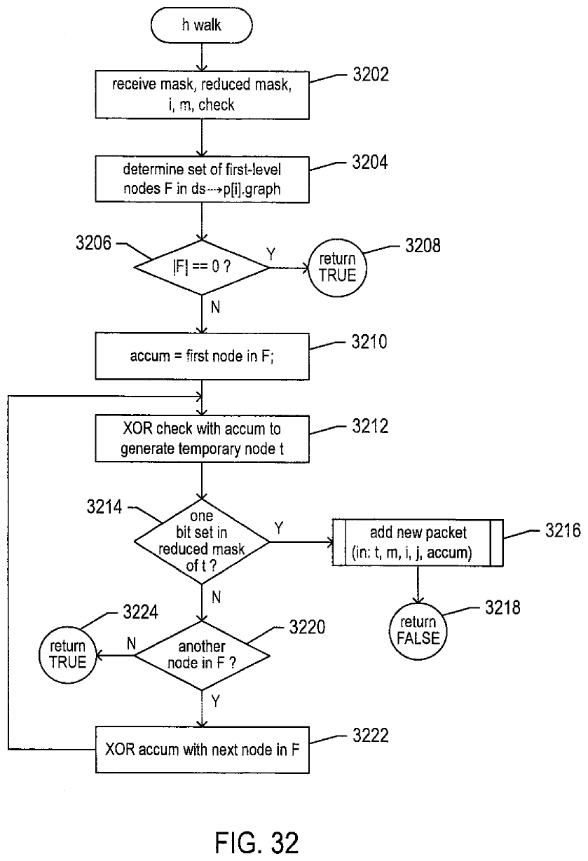

FIG. 32 provides a control-flow diagram for the routine “h walk,” called in step 2822 of FIG. 28. In step 3202, the routine “h walk” receives a mask and reduced mask prepared for a received check packet, an indication of a partition i, an indication of a message m, and the received check packet check. In step 3204, the routine “h walk” determines the set F of first-level graph nodes in the graph associated with the current partition. When there are no first-level nodes, as determined in step 3206, the routine “h walk” returns the value TRUE 3208. Otherwise, in step 3210, the routine “h walk” initializes an accumulated temporary graph node accum to be equal to the first first-level graph node in F. In step 3212, the routine “h walk” combines the check packet check with the temporary graph node accum in an XOR operation to generate a temporary node t. When the reduced mask in the temporary node t is only a single bit set, as determined in step 3214, then the routine “add new packet” is called, in step 3216, to carry out a data-packet reveal, following which the routine “h walk” returns the value FALSE in step 3218. Otherwise, if there is another first-level node in set F, as determined in step 3220, that next node in F is combined with accum to generate a new accum temporary node, in step 3222, and control flows back to step 3212. Note that, as described above, only indications of the check packets that will be combined by an XOR operation or multiple-XOR operation need be accumulated, and generation of the payload for the accumulated temporary node need not be carried out until it is clear that the temporary node can be used to reveal a new data packet. Otherwise, the routine “h walk” returns the value TRUE 3224.

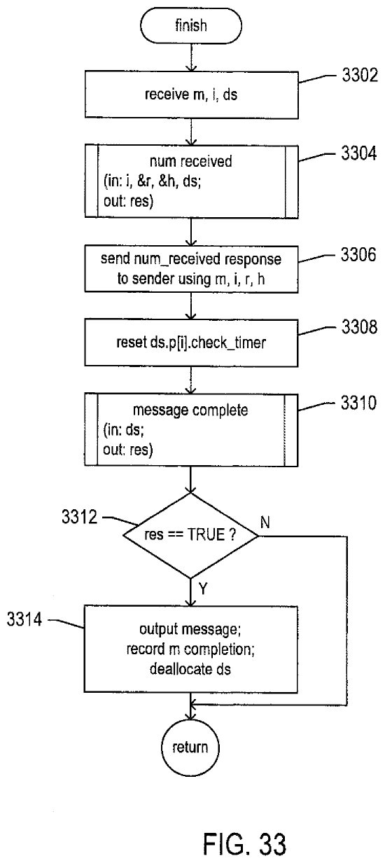

FIG. 33 provides a control-flow diagram for the routine “finish,” called in step 2810 of FIG. 28. The routine “finish” receives, in step 3302, an indication of a message m, an indication of a partition within the message i, and the data structure for the message ds. In step 3304, the routine “finish” calls the routine “num received” to determine the number of packets successfully received for partition i. In step 3306, the routine “finish” sends a num_received response to the sender. In step 3308, the routine “finish” resets the check timer for the partition i. In step 3310, the routine “finish” calls the routine “message complete” to determine whether or not the message m has not been successfully received. If so, as determined in step 3312, the message is output to a message consumer, completion of the message is recorded, and the data structure for the messages deallocated in step 3314.

The present invention has been described in terms of particular embodiments, it is not intended that the invention be limited to these embodiments. Modifications within the spirit of the invention will be apparent to those skilled in the art. For example, any of many different implementations of the currently disclosed FEC-based communications protocol can be obtained by varying various design and implementation parameters, including modular organization, control structures, data structures, hardware, operating system, and virtualization layers, and other such design and implementation parameters. There are a variety of possible different implementations that employ various alternative types of control flow and packet handling. The data structure can be varied to alternatively include additional information or to organize the needed information in different ways. As discussed above, the currently disclosed FEC-based communications protocol can be incorporated into existing communications-protocol levels within a communications-protocol stack or may constitute a separate, new medications protocol level in a communications-protocol stack. The communications protocol can support a variety of different types of multi-packet-message transmission and output.

1. A computer system that receives multi-packet messages using an XOR-based forward-error-correction communications protocol, the computer system comprising:
one or more processors;
one or more memories;
a data structure that includes one or more check-packet graphs, stored in one or more of the one or more memories; and
computer instruction, stored in one or more of the one or more memories, that, when executed by one or more of the one or more processors, control the computer system to
begin receiving and storing packets of a multi-packet message,
receive one or more check packets for the multi-packet message,
when a received check packet cannot be immediately used to reveal an unreceived multi-packet-message packet, represent the received check packet in a check-packet graph of the data structure; and
use a received check packet along with the data structure and one or more received multi-packet-message packets to reveal an unreceived multi-packet-message packet.

2. The computer system of claim 1 wherein the check-packet graphs of the data structure includes graph nodes that each includes:
a mask that indicates the multi-packet-message packets used to generate the check packet represented by the graph node;
a reduced mask that indicates the multi-packet-message packets used to generate the check packet represented by the graph node that have not already been received or revealed; and
one of the check packet represented by the graph node or a reference to the check packet represented by the graph node.

3. The computer system of claim 2 wherein the graph nodes of the check-packet graphs of the data structure further include 0, 1, or multiple pointers to higher-level graph nodes.

4. The computer system of claim 3 wherein first-level graph nodes represent received check packets and higher-level graph nodes represent derived check packets derived from a pair of check packets and/or derived check packets represented by lower-level graph nodes.

5. The computer system of claim 4 wherein a check packet is generated by one or an XOR operation that includes two multi-packet-message packets as operands or a multiple-XOR operation that includes more than two multi-packet-message packets as operands.

6. The computer system of claim 4 wherein, when the reduced mask in a graph node representing a check packet or derived check packet includes only a single indication of a multi-packet-message packet, the check packet or derived check packet represented by the graph node can be used as an operand in an XOR operation or a multiple-XOR operation along with one or more received or revealed multi-packet-message packets to reveal an unreceived multi-packet-message packet.

7. The computer system of claim 3 wherein the data structure includes a sequence of packet data structures that each represent one of the multiple multi-packet-message packets that together comprise a multi-packet message.

8. The computer system of claim 7 wherein each packet data structure either includes a sequence-number field or is associated with an index from which the sequence number can be computed.

9. The computer system of claim 8 wherein each packet data structure further includes:
a length field that indicates the length of the data payload of the multi-packet-message packet represented by the packet data structure; and
one of the multi-packet-message packet represented by the packet data structure or a reference to the multi-packet-message packet represented by the packet data structure.

10. The computer system of claim 9 wherein each packet data structure further includes:
0, 1, or multiple references to graph nodes that represent check packets generated, in part, from the multi-packet-message packet represented by the packet data structure.

11. The computer system of claim 7 wherein the data structure includes multiple partitions, each partition representing a sequentially ordered subset of the multi-packet-message packets that together compose the multi-packet message.

12. The computer system of claim 11 wherein each partition of the data structure includes:
packet data structures that represent the multi-packet-message packets represented by the partition; and
an rcvMask that indicates those multi-packet-message packets corresponding to packet data structures in the partition which have been received or generated by the computer system.

13. The computer system of claim 12 wherein each partition of the data structure may be associated with a check-packet graph representing received check packets and derived check packets referenced by one or more of the packet data structures of the partition.

14. The computer system of claim 12 wherein the packet data structures of the multiple partitions of the data structure form logical circular set of packet data structures, with an in pointer indicating a position at which a new partition can be added to the data structure and an out pointer indicating a position from which a partition can be removed from the data structure.

15. A method for storing check packets in a data structure used by a computer system to facilitate reliable reception of a multi-packet message, the method comprising:
initializing the data structure to provide for storing multiple partitions of the multi-packet message, each partition comprising multiple multi-packet-message packets;
receiving and storing multi-packet-message packets of the multi-packet message,
receiving one or more check packets for the multi-packet message,
when a received check packet cannot be immediately used to reveal an unreceived multi-packet-message packet, representing the received check packet as a graph node in a check-packet graph of the data structure; and
using a received check packet along with the data structure and one or more of one or more received or revealed multi-packet-message packets to reveal an unreceived multi-packet-message packet.

16. The method of claim 15
wherein the check-packet graphs of the data structure includes graph nodes that each includes
a mask that indicates the multi-packet-message packets used to generate the check packet represented by the graph node,
a reduced mask that indicates the multi-packet-message packets used to generate the check packet represented by the graph node that have not already been received or revealed; and
one of the check packet represented by the graph node or a reference to the check packet represented by the graph node:
wherein the graph nodes of the check-packet graphs of the data structure further include 0, 1, or multiple pointers to higher-level graph nodes; and
wherein first-level graph nodes represent received check packets and higher-level graph nodes represent derived check packets derived from a pair of check packets and/or derived check packets represented by lower-level graph nodes.

17. The method of claim 16
wherein a check packet is generated by one or an XOR operation that includes two multi-packet-message packets as operands or a multiple-XOR operation that includes more than two multi-packet-message packets as operands; and
wherein, when the reduced mask in a graph node representing a check packet or derived check packet includes only a single indication of a multi-packet-message packet, the check packet or derived check packet represented by the graph node can be used as an operand in an XOR operation or a multiple-XOR operation along with one or more received or revealed multi-packet-message packets to reveal an unreceived multi-packet-message packet.

18. The method of claim 16
wherein the data structure includes a sequence of packet data structures that each represent one of the multiple multi-packet-message packets that together comprise a multi-packet message;
wherein each packet data structure either includes a sequence-number field or is associated with an index from which the sequence number can be computed;
wherein each packet data structure further includes
a length field that indicates the length of the data payload of the multi-packet-message packet represented by the packet data structure, and
one of the multi-packet-message packet represented by the packet data structure or a reference to the multi-packet-message packet represented by the packet data structure; and
wherein each packet data structure further includes 0, 1, or multiple references to graph nodes that represent check packets generated, in part, from the multi-packet-message packet represented by the packet data structure.

19. The method of claim 18
wherein the data structure includes multiple partitions, each partition representing a sequentially ordered subset of the multi-packet-message packets that together compose the multi-packet message;
wherein each partition of the data structure includes
packet data structures that represent the multi-packet-message packets represented by the partition, and
an rcvMask that indicates those multi-packet-message packets corresponding to packet data structures in the partition which have been received or generated by the computer system;
wherein each partition of the data structure may be associated with a check-packet graph representing received check packets and derived check packets, the received check packets referenced by one or more of the packet data structures of the partition.

20. A physical data-storage device that stores computer instructions that, when executed by one or more processors of a computer system or other processor-controlled device, control the computer system or other processor controlled device to:
initialize the data structure to provide for storing multiple partitions of the multi-packet message, each partition comprising multiple multi-packet-message packets;
receive and storing multi-packet-message packets of the multi-packet message,
receive one or more check packets for the multi-packet message,
when a received check packet cannot be immediately used to reveal an unreceived multi-packet-message packet, represent the received check packet as a graph node in a check-packet graph of the data structure; and
use a received check packet along with the data structure and one or more of one or more received or revealed multi-packet-message packets to reveal an unreceived multi-packet-message packet.
